(19) United States
(12) Patent Application Publication
(10) Pub. No.: US 2015/0247289 A1
(43) Pub. Date: Sep. 3, 2015

(54) LAMINATE AND COMPOSITE

(71) Applicant: SUMITOMO BAKELITE CO., LTD., Tokyo (JP)

(72) Inventors: Tatsumi Kawaguchi, Tokyo (JP); Yasutaka Kimura, Tokyo (JP)

(73) Assignee: SUMITOMO BAKELITE CO., LTD., Tokyo (JP)

(21) Appl. No.: 14/430,442

(22) PCT Filed: Sep. 2, 2013
(86) PCT No.: PCT/JP2013/073514

§ 371 Date: Mar. 23, 2015

(30) Foreign Application Priority Data
Oct. 2, 2012 (JP) 2012-220289

(51) Int. Cl. D21H 27/30; H05K 9/00; D21H 17/52; D21H 17/00; D21H 17/67

(52) U.S. Cl. CPC D21H 27/30; D21H 17/74; D21H 17/67; D21H 17/52; H05K 9/0081

(57) ABSTRACT

According to the present invention, there is provided a laminate (1A) including a substrate (2) and a layer (8) which is provided on the substrate (2) and contains a fiber filler (fiber piece) and a resin. The layer (8) is a paper-making sheet obtained by subjecting the fiber filler and the resin to paper-making.

### TECHNICAL FIELD

The present invention relates to a laminate and a composite.

### BACKGROUND ART

In the related art, various substrates such as a flexible wiring substrate, a motherboard, and an interposer substrate have been used for a semiconductor device or the like (for example, Patent Document 1).

Further, substrates such as an optical circuit substrate and the like have been used for an optical device.

In these fields, for the purpose of saving energy, miniaturization, or shielding electromagnetic waves of a product, various techniques related to a case with excellent electromagnetic wave shielding performance or thermal conductivity have been suggested (for example, Patent Documents 2 and 3).

### RELATED DOCUMENT

### Patent Document

[Patent Document 1] Japanese Unexamined Patent Publication No. 2003-17817

[Patent Document 2] Japanese Unexamined Patent Publication No. 2006-278574

[Patent Document 3] Japanese Unexamined Patent Publication No. 2004-10668

### DISCLOSURE OF THE INVENTION

There is a limitation to functions which can be expressed in such a single substrate. For this reason, the present inventors considered providing a layer capable of expressing various performances according to the purpose of a substrate. In addition, the present inventors considered using a composite having various functions as a case that accommodates an electronic device.

According to the present invention, there is provided a laminate including: a substrate; and a layer which is provided on the substrate, contains a fiber filler and a resin, and is obtained by subjecting the fiber filler and the resin to paper-making.

In the present invention, a layer obtained by subjecting a fiber filler and a resin to paper-making is provided on the substrate. A layer having functions in accordance with various purposes can be obtained by suitably selecting the kind and amount of a fiber filler and the kind and amount of a resin for this layer.

Accordingly, such a laminate has a new function that is difficult to obtain in a single substrate.

Further, according to the present invention, there is provided a composite including: a first portion which contains a first fiber filler and a first resin and is obtained by subjecting the first fiber filler and the first resin to paper-making; and a second portion which contains a second fiber filler and a second resin and is obtained by subjecting the second fiber filler and the second resin to paper-making.

In the present invention, at least two portions obtained by subjecting a fiber filler and a resin to paper-making are provided. By suitably selecting the kinds or amounts of the fiber filler and the resin used for each portion, it is possible to provide desirable functions for each portion. Therefore, such a composite can have plural functions.

According to the present invention, it is possible to provide a laminate having new functions.

### BRIEF DESCRIPTION OF THE DRAWINGS

The above-described object, another object, characteristics, and advantages will be described with reference to preferred embodiments described below and the accompanying drawings.

FIG. 1 is a cross-sectional view taken along a lamination direction of a laminate according to an embodiment of the present invention.

FIG. 2 is a cross-sectional view taken along a lamination direction of a laminate according to an embodiment of the present invention.

FIG. 3 is a cross-sectional view taken along a lamination direction of a laminate according to an embodiment of the present invention.

FIG. 4 is a cross-sectional view taken along a lamination direction of a laminate according to an embodiment of the present invention.

FIG. 5 is a view illustrating a process of producing a paper-making sheet.

FIG. 6 is a view schematically illustrating the state of a fiber filler in the paper-making sheet and a portion surrounded by a circle in FIG. 6 illustrates the state of the fiber filler when the paper-making sheet is seen in a plan view.

FIG. 7(a) is a view illustrating a method of producing a paper-making sheet and FIG. 7(b) is a cross-sectional view taken along the thickness direction of the paper-making sheet.

FIG. 8 is a cross-sectional view illustrating a modified example of the present invention.

FIG. 9 illustrates a modified example of the paper-making sheet. FIG. 9(a) is a cross-sectional view taken along the thickness direction of the paper-making sheet and FIG. 9(b) is a view illustrating paper-making sheets being laminated.

FIG. 10 is a cross-sectional view taken along the lamination direction of a composite according to an embodiment of the present invention.

FIG. 11 is a view illustrating a process of producing a composite.

FIG. 12 is a view illustrating a composite according to an embodiment of the present invention.

FIG. 13 is a top view of a composite according to an embodiment of the present invention.

FIG. 14 illustrates a composite according to an embodiment of the present invention. FIG. 14(a) is a top view of the composite and FIG. 14(b) is a cross-sectional view taken along the lamination direction of the composite.

FIG. 15 is a view illustrating a process of producing a composite.

FIG. 16 is a view illustrating a composite according to an embodiment of the present invention.

FIG. 17 is a view illustrating a process of producing a composite having an opening portion.

### DESCRIPTION OF EMBODIMENTS

Hereinafter, embodiments of the present invention will be described with reference to the accompanying drawings. Further, in all drawings, the same reference numerals are denoted to the same constituent elements and the description thereof will not be repeated.

### First Embodiment

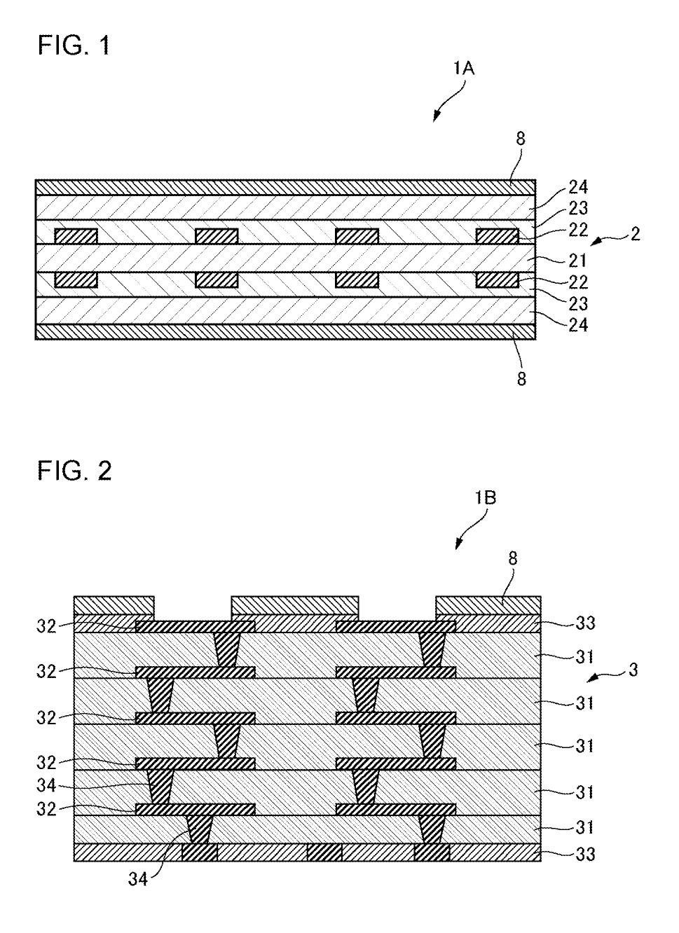

First, the outline of an article according to a first embodiment of the present invention will be described with reference to FIGS. 1 to 4.

Laminates (1A to 1D) include substrates (2 to 5) and a layer (hereinafter, referred to as a “paper-making sheet”) 8 that is provided on the substrates, contains a fiber filler (fiber piece) and a resin, and is obtained by subjecting the fiber filler and the resin to paper-making.

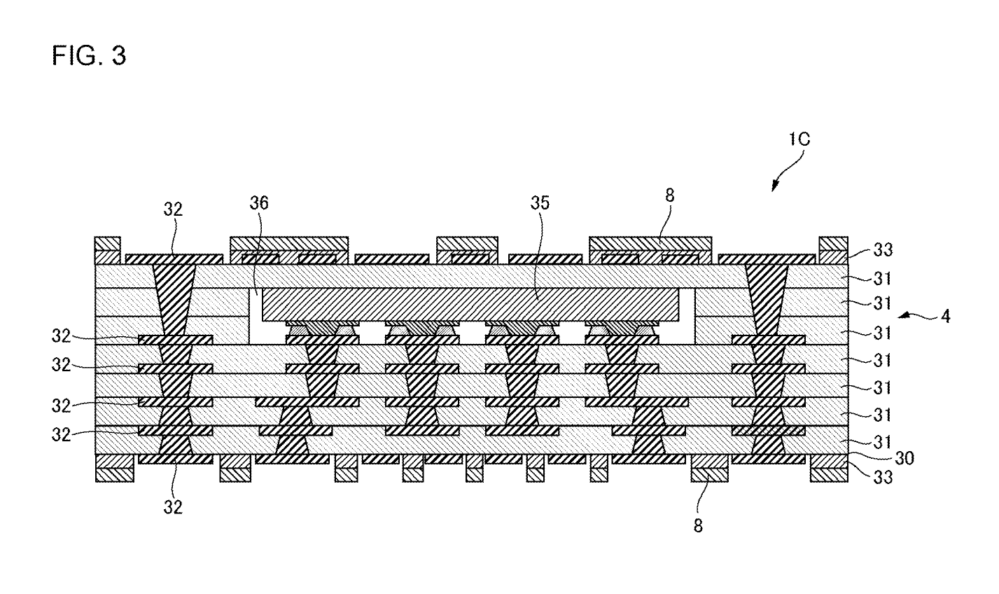

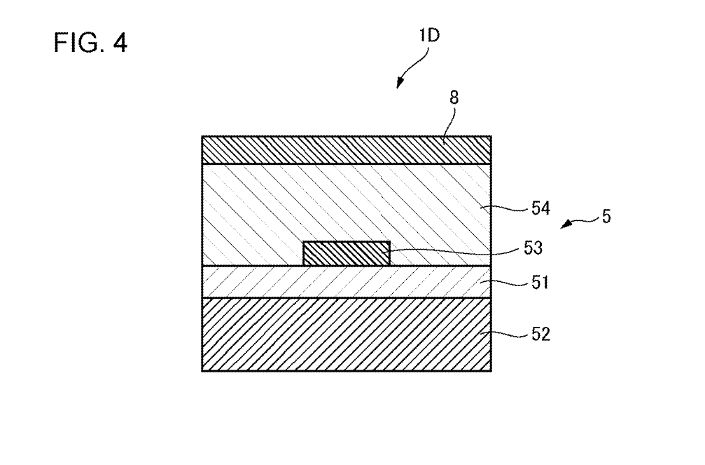

In FIG. 1, a substrate 2 is a flexible wiring substrate. In FIG. 2, a substrate 3 is an interposer substrate and is also a build-up wiring substrate. In FIG. 3, a substrate 4 is a component built-in substrate. In FIG. 4, a substrate 5 is an optical waveguide substrate.

In addition, the substrate is not limited to those described above and, for example, a motherboard or the like may be used.

Moreover, as the substrate, a substrate which contains a fiber filler (fiber piece) and a resin and is obtained by subjecting the fiber filler and the resin to paper-making may be used. The substrate obtained using the paper-making method can be produced by the same method as that of the paper-making sheet 8. Further, the composition of the substrate obtained using the paper-making method may be the same as or different from the composition of the paper-making sheet 8 described above.

Such a laminate includes the paper-making sheet 8 and thus has a new function that is difficult to obtain in a single substrate by suitably selecting the kind and amount of the fiber filler and the kind and amount of the resin, or the like, contained in the paper-making sheet 8.

Hereinafter, each configuration of the laminate will be described in detail.

(Paper-Making Sheet)

The paper-making sheet 8 is formed of a composite material composition. The composite material composition contains a fiber filler (A) and a resin (B) as constituent materials.

The kind of fiber filler (A) varies according to the characteristics required for the paper-making sheet 8, and examples thereof include metal fibers; natural fibers such as wood fibers, cotton, hemp, and wool; regenerated fibers such as rayon fibers; semi-synthetic fibers such as cellulose fibers; synthetic fibers such as polyamide fibers, aramid fibers, polyimide fibers, polyvinyl alcohol fibers, polyester fibers, acrylic fibers, poly-p-phenylene benzoxazole fibers, polyethylene fibers, polypropylene fibers, polyacrylonitrile fibers, and ethylene vinyl alcohol fibers; carbon fibers; and inorganic fibers such as glass fibers and ceramic fibers.

These fibers may be used alone or in combination of two or more kinds thereof.

Further, in a case where the paper-making sheet 8 having thermal conductivity or the paper-making sheet 8 having electromagnetic wave shielding performance is produced, it is preferable that the fiber filler (A) contains at least one of metal fibers or carbon fibers as a main component.

Further, in a case where the paper-making sheet 8 with high bending strength is produced, it is preferable that the fiber filler (A) contains any of polyamide fibers, aramid fibers, polyimide fibers, and poly-p-phenylene benzoxazole fibers.

Further, in the case where the paper-making sheet 8 with high bending strength is produced, it is preferable that the fiber filler (A) contains one of carbon fibers and inorganic fibers such as glass fibers and ceramic fibers.

The metal fibers may be metal fibers formed of a single metal element or synthetic fibers formed of plural metals, and it is preferable that metal elements constituting the metal fibers are one or more metals selected from a group consisting of aluminum, silver, copper, magnesium, iron, chromium, nickel, titanium, zinc, tin, molybdenum, and tungsten.

As the metal fibers in the present embodiment, stainless fibers (manufactured by Nippon Seisen Co., Ltd. or Bekaert Japan Co., Ltd.), copper fibers, aluminum fibers, brass fibers, steel fibers, titanium fibers, and phosphor bronze fibers (manufactured by Kogi Corporation Co., Ltd.) can be obtained as commercially available products, but the metal fibers are not limited thereto. These metal fibers may be used alone or in combination of two or more kinds thereof. Among these, one or more of copper fibers, aluminum fibers, and brass fibers are preferable from a viewpoint of thermal conductivity and one or more of stainless fibers, copper fibers, and aluminum fibers are preferable from a viewpoint of electromagnetic wave shielding properties.

In addition, the metal fibers may be used as they are, but metal fibers to which a surface treatment is applied using a silane coupling agent, an aluminate coupling agent, or a titanate coupling agent according to the required characteristics or metal fibers to which a convergence agent treatment is applied in order to improve adhesiveness with the resin and handleability thereof may be used.

Moreover, as fibers other than the metal fibers, for example, Kevlar (registered trademark) which is made from aramid fibers (manufactured by DU PONT-TORAY CO., LTD.); Technora (registered trademark) which is made from aramid fibers (manufactured by TEIJIN TECHNO PRODUCTS LIMITED); Vinylon which is made from polyvinyl alcohol fibers (manufactured by KURARAY CO., LTD.), Zylon (registered trademark) which is made from poly-p-phenylene benzoxazole fibers (manufactured by TOYOBO CO., LTD.); glass fibers (manufactured by Nitto Boseki Co., Ltd.); or Denkaarusen which are made from alumina fibers (manufactured by DENKI KAGAKU KOGYO KABUSHIKI KAISYA) can be obtained as commercially available products, but the fibers are not limited thereto.

As the shape of the fiber filler, which is not particularly limited, the fiber filler having a shape in accordance with the required characteristics can be used, but it is preferable to use chopped strands in a case of improving strength characteristics such as the bending strength or impact resistance using fibers other than metal fibers. Further, in order to obtain an effect of improving the yield, fibers which are beaten by mechanical shear force using a beater or a homogenizer, or fibrillated fibers are preferable. Such fibers are preferable in terms of having a large fiber surface area, high physical capturing ability against the resin, and chemically acting easily with a polymer coagulant (described below).

Further, the content of the fiber filler (A) according to the present embodiment is preferably in the range of 1% by mass to 90% by mass and particularly preferably equal to or more than 20% by mass and equal to or less than 80% by mass, and particularly preferably properly used according to the required necessity. For example, it is preferable that the content thereof is equal to or more than 1% by mass and less than 30% by mass based on the content of the entire composite material composition in a case where the processability or lightweight properties of the resin is required, it is preferable that the content thereof is equal to or more than 30% by mass and less than 60% by mass based on the content of the entire composite material composition in a case where the properties of the fiber filler and the resin need to be expressed in a highly balanced manner, and it is preferable that the content thereof is equal to or more than 30% by mass and equal to or less than 90% by mass based on the content of the entire composite material composition in a case where the properties of the fiber filler such as thermal conductivity or rigidity are required. The performance of the fiber filler can be expressed by adjusting the content of the fiber filler (A) to be equal to or more than 1% by mass based on the content of the entire composite material composition. Further, degradation of the lightweight properties and the processability of the paper-making sheet can be prevented by adjusting the content of the fiber filler (A) to be equal to or less than 90% by mass based on the content of the entire composite material composition.

Further, the fiber length of the fiber filler (A) according to the present embodiment, which is not particularly limited, is preferably properly used according to the required characteristics and, for example, the range thereof is preferably equal to or more than 500 μm and equal to or less than 10 mm. The characteristics of the fiber filler (A) such as thermal conductivity, electromagnetic wave shielding properties, and rigidity can be expressed by adjusting the fiber length to be equal to or more than 500 μm.

Further, forming workability can be secured by adjusting the fiber length thereof to be equal to or more than 500 μm and equal to or less than 10 mm. The forming workability indicates surface smoothness and releasability of a formed article.

From viewpoints of expressing characteristics of the fiber filler and securing the forming workability thereof, the fiber length of the fiber filler is preferably equal to or more than 1 mm and more preferably equal to or more than 3 mm and equal to or less than 8 mm.

Further, the diameter of the fiber filler (A) is preferably in the range of 1 μm to 100 μm and particularly preferably in the range of 5 μm to 80 μm. The rigidity of the composite material composition can be secured by adjusting the diameter thereof to be equal to or more than 1 μm and the forming workability can be secured by adjusting the diameter thereof to be equal to or less than 100 μm.

The length and the diameter of the fibers can be confirmed by, for example, observing the obtained paper-making sheet 8 with an electron microscope.

Further, the average fiber length and the average diameter of the fiber filler can be confirmed in the following manner.

The average length thereof can be acquired by selecting one hundred fiber fillers in total which are exposed to the surface of the paper-making sheet 8 and then calculating the average value thereof.

Further, the average length and the average diameter can be acquired by observing one hundred fiber fillers extracted from the paper-making sheet 8 and then calculating the average value thereof. In addition, the fiber fillers can be extracted by dissolving or melting the resin of the paper-making sheet 8.

In the present invention, the fiber fillers along with the resin can be suitably fluidized at the time of forming and, as a result, the fiber fillers in the obtained formed article are desirably uniformly dispersed. From a viewpoint of improving the fluidity, in the present invention, fiber fillers having an average fiber length of less than 500 μm can be used in addition to the above-described fiber fillers.

Examples of the fiber fillers which can be used from a viewpoint of improving the fluidity include milled fibers and cut fibers. When milled fibers are used, the heat resistance and the dimensional stability of the paper-making sheet to be obtained can be improved.

The resin (B) according to the present embodiment may be a thermoplastic resin or a thermosetting resin and is not particularly limited as long as the resin acts as a binder, and examples thereof include thermoplastic resins such as an acrylonitrile-styrene copolymer (AS) resin, an acrylonitrile-butadiene-styrene copolymer (ABS) resin, polycarbonate, polystyrene, polyvinyl chloride, a polyester resin, polyamide, a polyphenylene sulfide (PPS) resin, an acrylic resin, polyethylene, polypropylene, and a fluorine resin; and thermosetting resins such as a phenol resin, an epoxy resin, an unsaturated polyester resin, a melamine resin, and polyurethane. These resins can be suitably selected and then used according to the required characteristics. Further, these resins can be used alone or in combination of two or more kinds thereof. Among these, thermosetting resins are preferable from viewpoints of excellent mechanical strength and chemical resistance and thermoplastic resins are preferable from viewpoints that the formability is excellent and design properties such as transparency of resins are required.

The content of the resin (B) in the composite material composition is preferably equal to or more than 5% by mass and equal to or less than 90% by mass based on the entire composite material composition.

In this case, it is preferable that the content of the resin (B) is adjusted along with the adjustment of the content of the fiber fillers. In a case where the content of the fiber fillers is equal to or more than 20% by mass and equal to or less than 80% by mass, it is preferable that the content of the resin (B) is equal to or more than 10% by mass and equal to or less than 70% by mass based on the entire composite material composition. In a case where the content of the fiber fillers is equal to or more than 30% by mass and less than 60% by mass, it is preferable that the content of the resin (B) is equal to or less than 60% by mass and equal to or more than 30% by mass.

In a case where the content of the fiber fillers is equal to or more than 60% by mass and equal to or less than 90% by mass, it is preferable that the content of the resin (B) is equal to or more than 5% by mass and equal to or less than 30% by mass.

It is preferable that the composite material composition contains a powdery substance having ion exchange ability (C).

It is preferable that the powdery substance having the ion exchange ability (C) according to the present embodiment is at least one kind of intercalation compound selected from clay minerals, scaly silica microparticles, hydrotalcites, fluorine taeniolite, and swellable synthetic mica.

The clay minerals are not particularly limited as long as the substance has the ion exchange ability and examples thereof include smectitie, halloysite, kanemite, kenyaite, zirconium phosphate, and titanium phosphate. The hydrotalcites are not particularly limited as long as the substance has the ion exchange ability and examples thereof include hydrotalcite and a hydrotalcite-like substance. The fluorine taeniolite is not particularly limited as long as the substance has ion exchange ability and examples thereof include lithium type fluorine taeniolite and sodium type fluorine taeniolite. The swellable synthetic mica is not particularly limited as long as the substance has ion exchange ability and examples thereof include sodium type tetrasilicic fluorine mica and lithium type tetrasilicic fluorine mica. These intercalation compounds may be natural products or synthesized products and may be used alone or in combination of two or more kinds thereof. Among these, clay minerals are more preferable and smectite is still more preferable in terms that smectite exists in a form of a natural product or a synthetic product so that the range of selection is wide.

The smectite is not particularly limited as long as the substance has ion exchange ability and examples thereof include montmorillonite, beidellite, nontronite, saponite, hectorite, sauconite, and stevensite. Among these, any one or more kinds can be used. The montmorillonite is a hydrous silicate of aluminum, but may be bentonite that contains montmorillonite as a main component and minerals such as quartz, mica, feldspar, and zeolite. In a case where these substances are used for an application that is concerned with coloration or impurities, synthetic smectite with fewer impurities is preferable.

Further, as the powdery substance having the ion exchange ability (C), for example, Kunipia (bentonite) and Sumecton SA (synthetic saponite) (manufactured by KUNIMINE INDUSTRIES CO., LTD.), SUNLOVELY (scaly silica microparticles) (manufactured by AGC Si-Tech Co., Ltd.), Somasif (swellable synthetic mica) and Lucentite (synthetic smectite) (manufactured by CO-OP CHEMICAL CO., LTD.), and Hydrotalcite STABIACE HT-1 (hydrotalcite) (manufactured by SAKAI CHEMICAL INDUSTRY CO., LTD.) can be obtained as commercially available products, but the powdery substance is not limited thereto.

The content of the powdery substance having the ion exchange ability (C) is preferably equal to or more than 0.1% by mass and equal to or less than 30% by mass and more preferably equal to or more than 2% by mass and equal to or less than 20% by mass based on the entire composite material composition. When the content thereof is in the above-described range, an effect of improving fixing properties of constituent materials with different properties each other such as metal fibers contained in the fiber filler (A) and the resin (B) can be obtained. In addition, it is preferable that the content of the powdery substance having the ion exchange ability (C) is adjusted along with the adjustment of the ratio of the metal fibers contained in the fiber filler (A) and the resin (B) in the constituent material and the kind or the amount of a polymer coagulant.

It is preferable that the composite material composition contains the polymer coagulant (D).

The polymer coagulant, which will be described later, is used for aggregating the fiber filler (A) and the resin (B) in flocks. The polymer coagulant is not particularly limited by the ionicity or the like and a cationic polymer coagulant, an anionic polymer coagulant, a nonionic polymer coagulant, an amphoteric polymer coagulant, or the like can be used. Examples of these coagulants include cationic polyacrylamide, anionic polyacrylamide, Hofmann polyacrylamide, Man Nick polyacrylamide, amphoteric copolymer polyacrylamide, cationic starch, amphoteric starch, and polyethylene oxide. These polymer coagulants may be used alone or in combination of two or more kinds thereof. Further, in regard to the polymer coagulant, the polymer structure, the molecular weight, or the amount of functional groups such as a hydroxyl group or an ionic group is can be used without particular limitation in accordance with the required characteristics.

Moreover, as the polymer coagulant, for example, polyethylene oxide (manufactured by Wako Pure Chemical Industries, Ltd., Kanto Chemical Industry Co., Ltd., or Sumitomo Seika Chemicals Co., Ltd.), Hari Fix which is cationic PAM, Hamaido B-15 which is anionic PAM, and Hamaido RB-300 which is amphoteric PAM (manufactured by Harima Chemicals, Inc.), and SC-5 which is cationic starch (manufactured by Sanwa Starch Co., Ltd.) can be obtained as commercially available products, but the polymer coagulant is not limited thereto.

Moreover, the added amount of the polymer coagulant, which is not particularly limited, is preferably equal to or more than 100 mass ppm and equal to or less than 1% by mass based on the weight of the constituent materials. The added amount thereof is more preferably equal to or more than 500 mass ppm and equal to or less than 0.5% by mass. In this manner, constituent materials can be suitably aggregated. When the added amount of the polymer coagulant is less than the lower limit thereof, the yield may be decreased. In addition, when the added amount thereof is more than the upper limit thereof, the aggregation becomes extremely strong so that problems in dehydration or the like may occur.

For the composite material composition, for the purpose of improving characteristics, inorganic powder, metal powder, a stabilizer such as an antioxidant or a UV absorber, a release agent, a plasticizer, a flame retardant, a curing catalyst or a curing accelerator of a resin, a pigment, a paper strength enhancing agent such as a dry paper strength enhancing agent or a wet paper strength enhancing agent, a yield enhancing agent, a freeness enhancing agent, a size fixing agent, an anti-foaming agent, a sizing agent such as a rosin-based sizing agent for making acidic paper, a rosin-based sizing agent for making neutral paper, an alkyl ketene dimer sizing agent, an alkenyl succinic anhydride-based sizing agent, or a special modified rosin-based sizing agent, and a coagulant such as aluminum sulfate, aluminum chloride, or polyaluminum chloride and, for the purpose of adjusting production conditions and expressing required physical properties, various additives can be used in addition to the powdery substance having the ion exchangeability (C), the fiber filler (A), the resin (B), and the polymer coagulant (D) described above.

Further, examples of the inorganic powder include oxides such as titanium oxide, alumina, silica, zirconia, and magnesium oxide; nitrides such as boron nitride, aluminum nitride, and silicon nitride; sulfates such as barium sulfate, iron sulfate, and copper sulfate; hydroxides such as aluminum hydroxide and magnesium hydroxide; minerals such as kaolinite, talc, natural mica, and synthetic mica; and carbides such as silicon carbide. These may be used as they are, but inorganic powder obtained by applying a surface treatment thereto using a silane coupling agent, an aluminate coupling agent, or a titanate coupling agent according to the required characteristics may be used.

(Method of Producing Paper-Making Sheet 8)

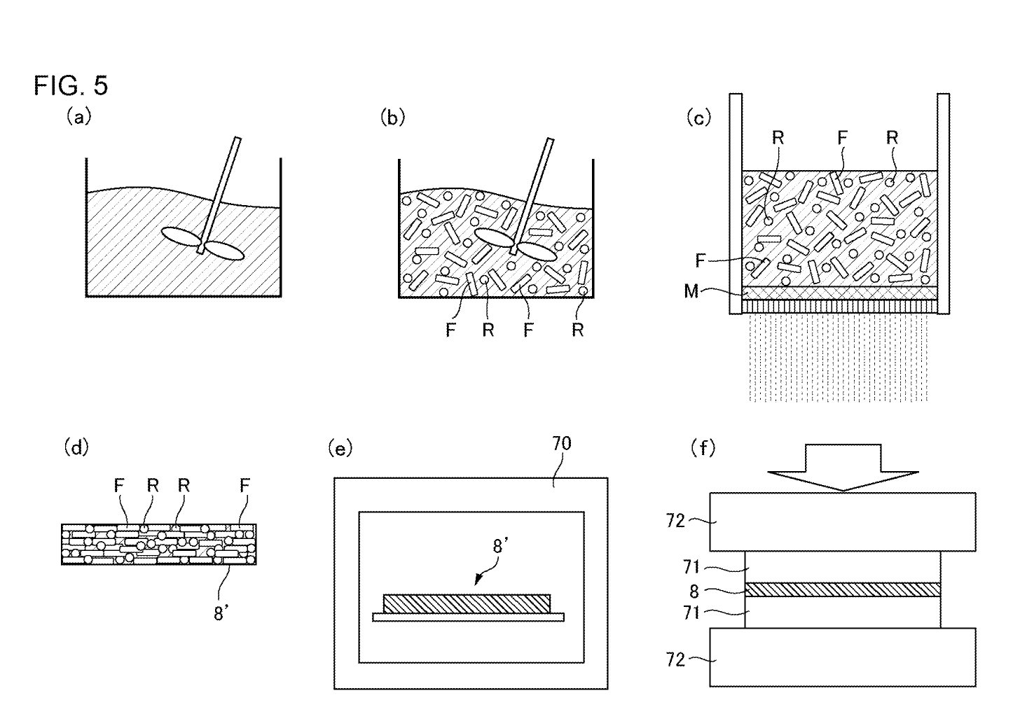

Next, a method of producing the paper-making sheet 8 will be described with reference to FIG. 5.

The paper-making sheet 8 can be produced according to a wet paper-making method and, for example, can be produced in the following manner.

Among the constituent materials of the above-described composite material composition, constituent materials from which a polymer coagulant is removed are added to a solvent, stirred, and then dispersed (see FIGS. 5(a) and 5(b)). As the method of dispersing the materials in the solvent, which is not particularly limited, a method of stirring using a disperser or a homogenizer can be exemplified.

In addition, in FIG. 5, the symbol F indicates the fiber filler and the symbol R indicates the resin.

The solvent is not particularly limited, but the boiling point thereof is preferably equal to or higher than 50° C. and equal to or lower than 200° C. from viewpoints that the solvent is unlikely to be volatilized during the process of dispersing the constituent materials of the composite material composition, the solvent is easily removed so that the solvent does not remain in the paper-making sheet 8, and an excessive amount of energy is needed for removing the solvent when the boiling point thereof is extremely high. Examples of such solvents include water; alcohols such as ethanol, 1-propanol, 1-butanol, and ethylene glycol; ketones such as acetone, methyl ethyl ketone, 2-heptanone, and cyclohexanone, esters such as ethyl acetate, butyl acetate, methyl acetoacetate, and methyl acetoacetate; and ethers such as tetrahydrofuran, isopropyl ether, dioxane, and furfural. These solvents can be used alone or in combination of two or more kinds thereof. Among these, water is particularly preferable in terms of the abundant amount of water to be supplied, low price, low environmental burden, high level of safety, and excellent handleability.

In addition, as the resin (B) which is a constituent material of the composite material composition, a resin whose average particle diameter is equal to or less than 500 μm in a solid state can be used. Further, the resin (B) may be in a state of emulsion having an average particle diameter of equal to or less than 500 μm. It is more preferable that the average particle diameter of the resin (B) is in the range of about 1 nm to 300 μm. In this manner, when a polymer coagulant is added, a state in which the resin and the fiber fillers are aggregated is easily formed and the yield is improved in the presence of a powdery substance having the ion exchange ability (C). Further, the average particle diameter of the resin (B) can be acquired, for example, by measuring the 50% particle diameter on a mass basis as the average particle diameter using a laser diffraction particle diameter distribution measuring apparatus such as SALD-7000 (manufactured by Shimadzu Corporation).

Subsequently, a polymer coagulant is added. In a case where the composite material composition includes a powdery substance having the ion exchange ability (C), the state in which the resin and the fiber fillers are aggregated is easily formed and constituent materials in a solvent are more easily aggregated in flocks because of the powdery substance having the ion exchange ability (C).

Next, as illustrated in FIG. 5(c), the solvent and the aggregated constituent materials (aggregates) are added to a container whose bottom surface is formed of a mesh M and a solvent is discharged from the mesh M. In this manner, the aggregates and the solvent are separated from each other (paper-making process).

Next, as illustrated in FIG. 5(d), sheet-like aggregates 8′ are extracted from the container illustrated in FIG. 5(c). Further, as illustrated in FIG. 5(e), the aggregates 8′ are put into a drying furnace 70, and are dried so that the solvent is further removed. Subsequently, aggregates 8′ are formed as illustrated in FIG. 5(f). In this manner, the paper-making sheet 8 can be obtained. As the forming method, press forming or the like can be exemplified. For example, as illustrated in FIG. 5(f), a sheet formed of aggregates 8′ is pressed by a pressing plate 71 and a hot plate 72 is arrange on the outer peripheral side of the pressing plate 71 and then heated. In this manner, the paper-making sheet 8 can be obtained.

In addition, in a case where a thermosetting resin is used as the resin contained in the paper-making sheet 8, it is preferable that the thermosetting resin is in a semi-cured state in the paper-making sheet 8 obtained in the above-described manner. The substrate and the paper-making sheet 8 can be fixed to each other by thermally curing the paper-making sheet 8 after the paper-making sheet 8 is laminated with the substrate when the thermosetting resin is in a semi-cured state.

Further, in the laminates 1A to 1D, the paper-making sheet 8 is in a C stage which is completely cured.

(Characteristics of Paper-Making Sheet 8)

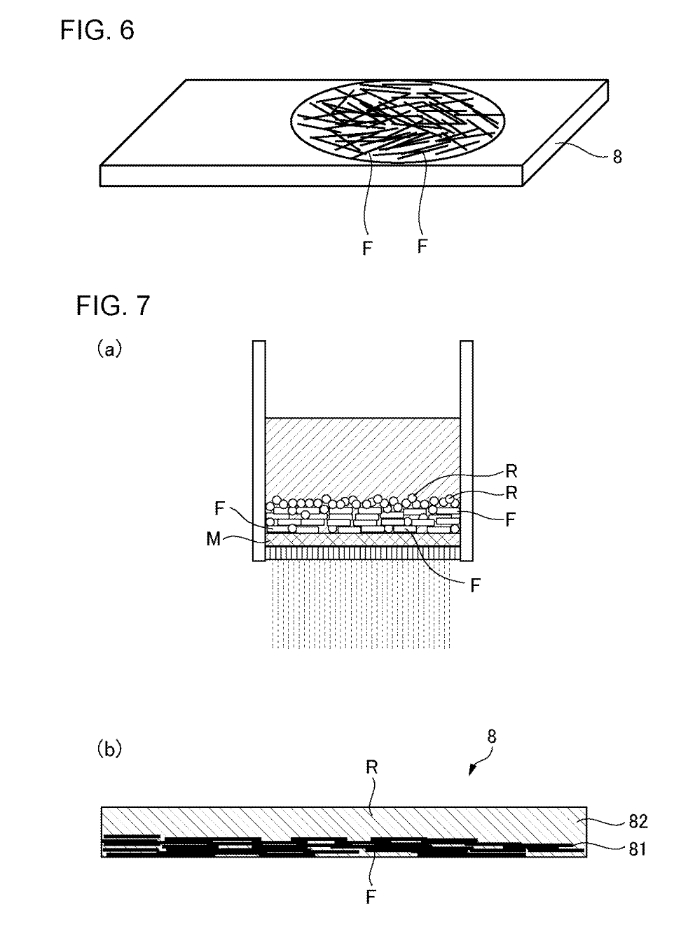

The paper-making sheet 8 of the present embodiment is produced according to the above-described paper-making method. For this reason, as illustrated in FIG. 6, most fiber fillers F are arranged such that the length direction of the fiber fillers F is along the in-plane direction of the sheet.

Meanwhile, when the paper-making sheet 8 is seen in a plan view as shown in the portion surrounded by a circle of FIG. 6, the fiber fillers F are randomly arranged in the plane of the sheet and entangled with each other.

Accordingly, for example, in a case where the fiber fillers are formed of thermal conductivity materials with high thermal conductivity, the thermal conductivity of the paper-making sheet 8 in the in-plane direction becomes extremely high. For example, the thermal conductivity of the paper-making sheet 8 in the in-plane direction can be equal to or more than 10 times the thermal conductivity thereof in the thickness direction.

In addition, the resin is interposed between the fiber fillers and plays a role of binding the fiber fillers to each other.

Further, as described above, in the paper-making sheet 8, the fiber fillers (A) F are moved to the mesh M side by their own weight when the solvent is discharged from the mesh M arranged on the bottom surface of the container as illustrated in FIG. 5(c) or FIG. 7(a). Depending on the content of the resin (B), the kind of fiber fillers (A), or the like in the paper-making sheet 8, the distance from the center position in the thickness of the fiber layer 81 formed of the fiber fillers (A) to one surface (front surface) of the resin layer 82 formed of the resin (B) may be different from the distance from the center position thereof to another surface (rear surface) of the resin layer in the paper-making sheet 8 as illustrated in the cross-sectional view of FIG. 7(b).

In addition, depending on the content of the resin (B) the kind of fiber fillers (A), or the like in the paper-making sheet 8, plural voids may be formed in the inside of the fiber layer formed of the fiber fillers (A). In this manner, the weight of the paper-making sheet 8 can be reduced.

Various characteristics of the paper-making sheet 8 can be exhibited by suitably setting the kind and the content of the fiber fillers and the kind and the content of the resin.

For example, it is possible to make the paper-making sheet 8 with excellent electromagnetic wave shielding performance and thermal conductivity by using metal fibers, carbon fibers, or the like as the fiber fillers so that it is possible to protect the substrate from electromagnetic waves, and to conduct the heat from the substrate to other components. In addition, it is possible to make the paper-making sheet 8 with high thermal conductivity by using metal fibers, carbon fibers, or the like as the fiber fillers so that it is possible to protect the substrate by conducting the heat from the substrate.

Moreover, it is possible to protect the substrate by making the paper-making sheet 8 with high rigidity by suitably selecting the fiber fillers.

(Substrate)

Next, a substrate included in the laminate will be described with reference to FIGS. 1 to 4.

(Flexible Wiring Substrate)

The laminate 1A illustrated in FIG. 1 includes the substrate 2 and the paper-making sheet 8.

The substrate 2 is a flexible wiring substrate and includes a resin film 21, a circuit layer 22 provided on the front and rear surfaces of the resin film 21, a coverlay film 24 covering each circuit layer 22, and an adhesive layer 23 provided between the coverlay film 24 and the circuit layer 22.

The paper-making sheet 8 is provided on each coverlay film 24.

The resin film 21 is, for example, a film made of polyimide and the adhesive film 23 is made of an epoxy-based adhesive. The circuit layer 22 is, for example, a circuit made of copper. The coverlay film 24 may be a polyimide film or a polyester film.

There are various methods as a method of attaching the paper-making sheet 8 to the substrate 2. For example, the paper-making sheet 8 may be attached to the substrate 2 through an adhesive. Further, the paper-making sheet 8 in a semi-cured state is pressure-bonded onto the substrate 2 and then the substrate 2 and the paper-making sheet 8 are heated. The paper-making sheet 8 may be fixed to the substrate 2 by being heated and cured. In this case, the paper-making sheet 8 is brought into direct contact with the substrate 2.

The method of attaching the paper-making sheet 8 to the substrate is the same in a case where the paper-making sheet is attached to another substrate described below.

(Build-Up Substrate)

The laminate 1B illustrated in FIG. 2 includes the substrate 3 and the paper-making sheet 8.

The substrate 3 is a build-up substrate and includes an insulating resin layer 31 which is a build-up layer and a circuit layer 32, and these are alternately laminated with each other.

A core layer does not exist in the substrate 3, but a build-up substrate on which a build-up layer and a circuit layer are alternately laminated on the front and rear surfaces of a core layer may be used.

In a case where the substrate 3 includes a core layer, a resin material of the resin layer 31 can be used as the resin material of the core layer.

A via 34 connects between the circuit layers 32.

The resin layer 31 may be a prepreg obtained by impregnating various resins into woven fabrics of carbon fibers or glass fibers or into fibers aligned in one direction. Further, the resin layer 31 may be formed of only a resin composition. It is preferable that the resin layer 31 is not reinforced by fibers such as carbon fibers or glass fibers.

Here, examples of the resin constituting the resin layer 31 include an epoxy resin, a BT resin, and a cyanate resin. One or more kinds thereof can be used. Among these, a cyanate resin is preferably used. Examples of the cyanate resin include a novolac type cyanate resin, a bisphenol A type cyanate resin, a bisphenol E type cyanate resin, and a tetramethyl bisphenol F type cyanate resin. Among these, a novolac type cyanate resin is preferably used.

As the novolac type cyanate resin, a resin represented by the following chemical formula can be used. In the formula, n represents an integer of equal to or more than 1.

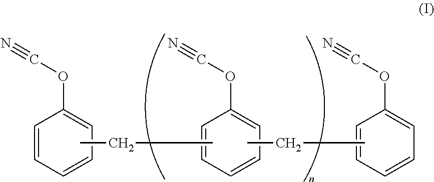

Such a novolac type cyanate resin can be obtained, for example, by reacting novolac type phenol with a compound such as cyanogen chloride or cyanogen bromide.

Moreover, as the cyanate resin, a naphthol type cyanate resin represented by the following general formula (II) is also preferably used. The naphthol type cyanate resin represented by the following general formula (II) is obtained by condensing cyanic acid and a naphthol aralkyl resin obtained by reacting naphthols such as α-naphthol and β-naphthol with p-xylylene glycol, α,α′-dimethoxy-p-xylene, or 1,4-di(2-hydroxy-2-propyl)benzene. It is more preferable that n in the general formula (II) is equal to or less than 10. When n is equal to or less than 10, there is a tendency that the resin viscosity is not increased, the impregnating ability into the substrate is excellent, and the performance as an element mounting substrate is not degraded. Further, there is a tendency that intramolecular polymerization is unlikely to occur at the time of synthesis, the liquid separation properties at the time of washing are improved, and a decrease in yield can be prevented.

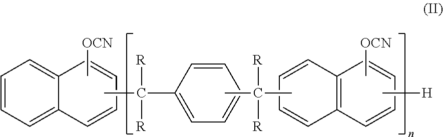

(In the formula, R represents a hydrogen atom or a methyl group and n represents an integer of equal to or more than 1.)

Further, as the cyanate resin, a dicyclopentadiene type cyanate resin represented by the following general formula (III) is also preferably used. In the dicyclopentadiene type cyanate resin represented by the following general formula (III), it is more preferable that n in the following general formula (III) is equal to or more than 0 and equal to or less than 8. When n is equal to or less than 8, the resin viscosity is not increased, the impregnating ability into the substrate is excellent, and degradation of the performance as an element mounting substrate can be prevented. In addition, when dicyclopentadiene type cyanate resin is used, the substrate has excellent low hygroscopicity and chemical resistance.

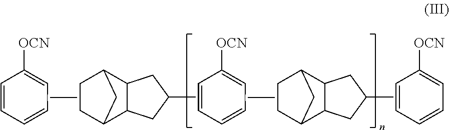

(n represents an integer of equal to or more than 0 and equal to or less than 8.)

The weight average molecular weight (Mw) of the cyanate resin, which is not particularly limited, is preferably equal to or more than 500 and equal to or less than 4500 and particularly preferably equal to or more than 600 and equal to or less than 3000. In a case where Mw is extremely small, since a resin layer becomes sticky when produced, resin layers may be adhered to each other when they are in contact with each other or a transfer of the resin may occur. Further, in a case where Mw is extremely large, since the reaction becomes extremely fast, forming failure may occur or the interlayer peeling strength may be decreased when a circuit substrate is produced.

The Mw of the cyanate resin or the like can be measured, for example, using GPC (gel permeation chromatography, standard substance: polystyrene conversion).

In addition, although not limited to the following, the cyanate resins may be used alone or in combination of two or more kinds having Mws different from each other, or one or more kinds thereof and a prepolymer thereof may be used in combination.

The content of the cyanate resin, which is not particularly limited, is preferably equal to or more than 5% by mass and equal to or less than 50% by mass and more preferably equal to or more than 10% by mass and equal to or less than 40% by mass based on the entire resin composition of the resin layer 31. When the content of the cyanate resin is adjusted to be equal to or more than 5% by mass, the heat resistance can be improved. Further, when the content thereof is adjusted to be equal to or less than 50% by mass, a decrease in moisture resistance can be prevented.

In addition, an epoxy resin, a phenoxy resin, or the like may be added to the cyanate resin. As the epoxy resin, an epoxy resin having a biphenyl alkylene skeleton is preferable.

Further, it is preferable that the resin layer 31 contains a phenoxy resin that does not substantially contain a halogen atom. In this manner, film forming properties at the time of producing the resin layer 31 can be improved. Here, the expression “does not substantially contain a halogen atom” means, for example, that the content of the halogen atom in a phenoxy resin is equal to or less than 1% by mass.

Examples of the phenoxy resin, which is not particularly limited, include a phenoxy resin having a bisphenol skeleton; a phenoxy resin having a novolac skeleton; a phenoxy resin having a naphthalene skeleton, and a phenoxy resin having a biphenyl skeleton. Further, a phenoxy resin having a structure with plural kinds of these skeletons can be used. Among these, one or more kinds can be used. Further, a phenoxy resin having a biphenyl skeleton and a bisphenol S skeleton can be used. In this manner, it is possible to raise the glass transition temperature using the rigidity of the bisphenol skeleton and to increase the adhesiveness of plated metals using a bisphenol S skeleton. Moreover, a phenoxy resin having a bisphenol A skeleton and a bisphenol F skeleton may be used. In addition, a phenoxy resin having the above-described biphenyl skeleton and bisphenol S skeleton and a phenoxy resin having a bisphenol A skeleton and a bisphenol F skeleton may be used in combination. In this manner, it is possible to express these characteristics in a well-balanced manner.

The molecular weight of the phenoxy resin is not particularly limited, but it is preferable that the weight average molecular weight is equal to or more than 5000 and equal to or less than 50000 and more preferable that the weight average molecular weight is equal to or more than 10000 and equal to or less than 40000. When the weight average molecular weight is adjusted to be equal to or more than 5000, the film forming properties can be improved. Further, when the average molecular weight is adjusted to be equal to or less than 50000, a decrease in solubility of the phenoxy resin can be prevented.

The content of the phenoxy resin, which is not particularly limited, is preferably equal to or more than 1% by mass and equal to or less than 40% by mass and more preferably equal to or more than 5% by mass and equal to or less than 30% by mass based on the entire resin composition of the resin layer 31. When the content thereof is less than 1% by mass, an effect of improving the film forming properties is decreased in some cases. In addition, when the content thereof exceeds 40% by mass, low thermal expansion properties are decreased in some cases.

The resin layer 31 may contain an imidazole compound as a curing agent. In this manner, when the resin layer 31 contains a cyanate resin or an epoxy resin, a reaction of these resins can be promoted without decreasing the insulation properties of the resin layer 31. Examples of the imidazole compound, which is not particularly limited, include 2-phenyl-4-methylimidazole, 2-phenyl-4-methyl-5-hydroxymethylimidazole, 2-phenyl-4,5-dihydroxymethylimidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methylamidazolyl-(1′)]-ethyl-s-triazine, and 1-benzyl-2-phenylimidazole. Among these, an imidazole compound having two or more functional groups selected from an aliphatic hydrocarbon group, an aromatic hydrocarbon group, a hydroxyalkyl group, and a cyanoalkyl group is preferable and 2-phenyl-4,5-dihydroxymethylimidazole is particularly preferable. In this manner, it is possible to improve the heat resistance of the resin layer 31 and to decrease the thermal expansion coefficient and the water absorption rate of the resin layer 31.

In a case where the resin layer 31 contains the cyanate resin and the epoxy resin, the content of the imidazole compound, which is not particularly limited, is preferably equal to or more than 0.1% by mass and equal to or less than 5% by mass and particularly preferably equal to or more than 0.3% by mass and equal to or less than 3% by mass based on the total content of these resins. In this manner, particularly the heat resistance can be improved.

The average linear expansion coefficient (equal to or higher than 25° C. and equal to or lower than the glass transition point) of the resin layer 31 in the substrate in-plane direction is equal to or less than 35 ppm/° C. Further, the average linear expansion coefficient of the resin layer 31 of the substrate 3 in the substrate in-plane direction is preferably equal to or less than 30 ppm/° C.

In addition, the linear expansion coefficient of the resin layer 31 is measured using a TMA device (manufactured by TA Instruments).

The circuit layer 32 is a circuit made of, for example, copper. Further, a solder resist film 33 is provided on the surface of the circuit layer 32 and the paper-making sheet 8 is provided on the solder resist film 33.

In the present embodiment, similarly to the solder resist film 33, an opening portion is formed in the paper-making sheet 8 and a part of the circuit layer 32 is exposed from the opening portion.

The solder resist film 33 is attached onto the circuit layer 32 and the paper-making sheet 8 is arranged on the solder resist film 33. Further, an opening portion penetrating the paper-making sheet 8 and the solder resist film 33 is formed using a laser or the like.

(Component Built-In Substrate)

A laminate 1C of FIG. 3 includes the substrate 4 and the paper-making sheet 8 provided on the substrate 4.

The substrate 4 includes a substrate main body 30 and an element 35 accommodated in the inside of the substrate main body 30.

The substrate main body 30 is a build-up substrate on which the above-described resin layer 31 and the circuit layer 32 are alternately laminated and an accommodating space 36 which accommodates the element 35 is formed.

The element 35 is, for example, a semiconductor element.

The paper-making sheet 8 is provided on the solder resist film 33 of the substrate main body 30.

(Optical Waveguide Substrate)

The laminate 1D of FIG. 4 includes the substrate 5 and the paper-making sheet 8 provided on the substrate 5.

The substrate 5 is an optical waveguide substrate and includes a base material 52 such as a silicon wafer, a clad layer 51 provided on the base material 52, a core layer 53 provided on the clad layer 51, and a clad layer 54 covering the core layer 53. In addition, the paper-making sheet 8 is provided on the clad layer 54.

All the clad layers 51 and 54 and the core layer 53 are made of a resin and can be formed using, for example, an acrylic-based or epoxy-based UV curable resin.

Further, the clad layers 51, 54, and the core layer 53 may be obtained by curing a photosensitive norbornene resin composition.

In addition, here, the laminate 1D includes an optical waveguide substrate, but another optical circuit substrate (optical fibers or the like) in place of the optical waveguide substrate similarly can be included in a laminate including a paper-making sheet. That is, the laminate includes an optical circuit substrate other than the optical waveguide substrate such as optical fibers and the paper-making sheet 8 may be provided on the optical circuit substrate.

Hereinbefore, the embodiments of the present invention have been described, but these are merely examples of the present invention and various configurations other than those described above can be employed.

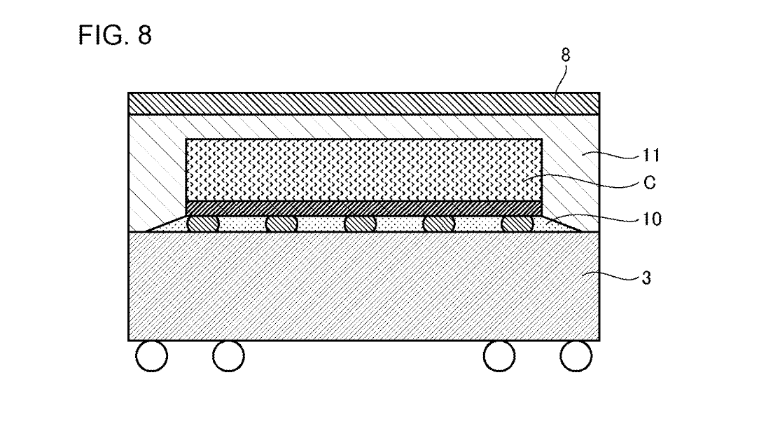

For example, in the above-described embodiments, the paper-making sheet 8 was attached to each substrate directly or through an adhesive, but the configuration is not limited thereto. For example, the paper-making sheet 8 may be provided on a sealing material 11 as illustrated in FIG. 8. In this case, for example, the fiber fillers of the paper-making sheet 8 can have electromagnetic wave shielding performance by being formed of a conductive material. In addition, in FIG. 8, the symbol C indicates a semiconductor chip and the reference numeral 10 indicates an underfill.

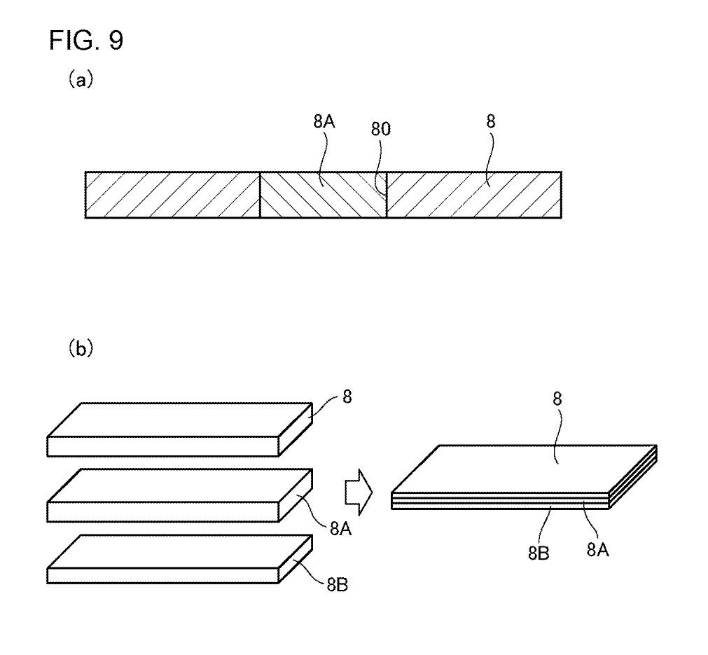

In addition, as illustrated in FIG. 9(a), a configuration in which the opening portion 80 is formed in the paper-making sheet 8 and another paper-making sheet 8A is fitted to the opening portion 80 may be employed.

Another paper-making sheet 8A contains a fiber filler and a resin similar to the paper-making sheet 8, but the composition of the composite material composition constituting the paper-making sheet 8A is different from the composition of the paper-making sheet 8.

Examples of the fiber filler and the resin used for the paper-making sheet 8A are the same as those described above.

In this manner, a region with different characteristics can be provided in the plane of the sheet.

Further, the laminate may include a substrate and plural paper-making sheets.

As illustrated in FIG. 9(b), paper-making sheets 8, 8A, and 8B having different compositions are prepared and these sheets are laminated and subjected to press forming. The paper-making sheet 8B contains a fiber filler and a resin similar to the paper-making sheet 8, but the composition of the composite material composition constituting the paper-making sheet 8B is different from those of the paper-making sheets 8 and 8A.

### Second Embodiment

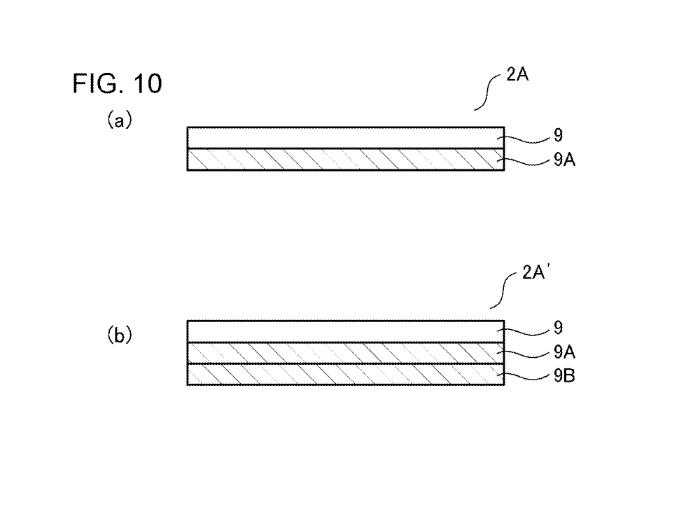

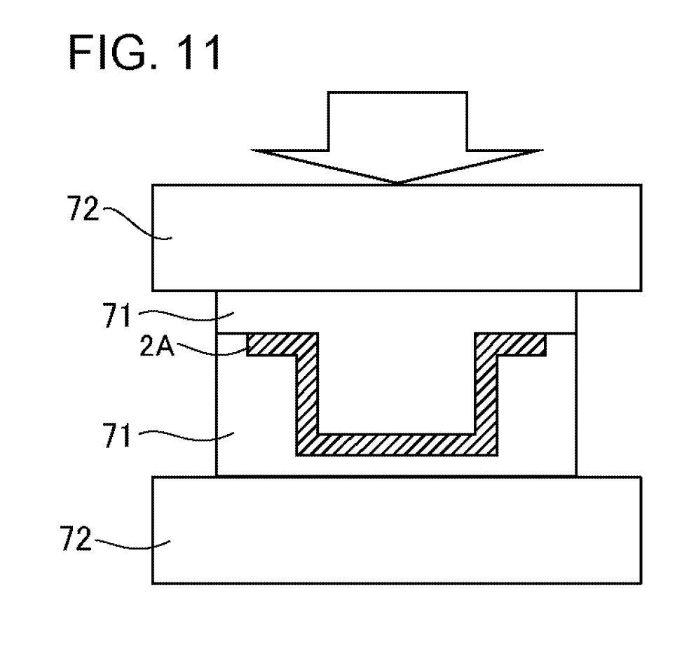

The outline of a composite according to a second embodiment of the present invention will be described with reference to FIG. 10.

As illustrated in FIG. 10, a composite 2A includes a first portion 9 which contains a first fiber filler and a first resin and is obtained by subjecting the first fiber filler and the first resin to paper-making and a second portion 9A which contains a second fiber filler and a second resin and is obtained by subjecting the second fiber filler and the second resin to paper-making.

In the present embodiment, the first portion 9 and the second portion 9A are layered, and the first portion 9 and the second portion 9A are laminated with each other (FIG. 10).

The first portion 9 and the second portion 9A constituting the composites 2A and 2B of the present embodiment are formed of a composite material composition containing the fiber filler (A) and the resin (B) which are the same as those used for producing the above-described paper-making sheet. Further, the first portion 9 and the second portion 9A can be produced using a production method which is the same method of producing the above-described paper-making sheet. The fiber filler (A), the resin (B), and other components used for the first portion 9 and the second portion 9A may be the same as or different from those used for the above-described paper-making sheet.

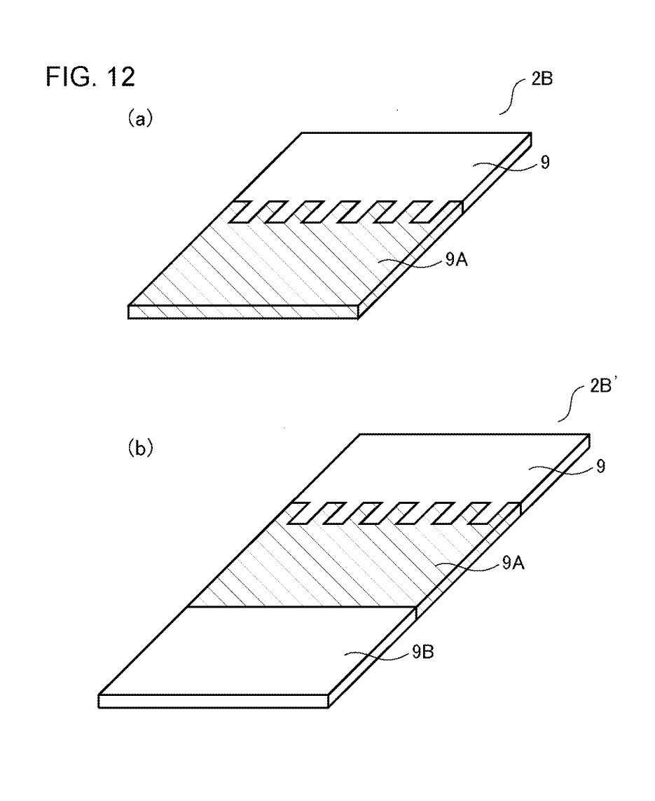

Examples of the method of laminating the first portion 9 and the second portion 9A include a heat press method, an adsorption method, and a spray coating method, but the method is not limited thereto. The lamination method can be suitably selected based on the kind of fiber filler and resin used for the first and second portions, the shape of a composite to be obtained, or the like. When a heat press method is used, two sheets of sheet-like aggregates are generated in the same manner as the method of producing the paper-making sheet 8 illustrated in FIGS. 5(a) to 5(e) described above. Next, two sheets of sheet-like aggregates are overlapped with each other and the sheet-like aggregates are heated and pressed by the pressing plate 71 as illustrated in FIG. 11. During the heat press process illustrated in FIG. 11, when a pressing plate having an uneven shape is used as the pressing plate 71 to press aggregates, it is possible to laminate two sheets of sheet-like aggregates with each other and to obtain a composite which is subjected to bending processing into a desired shape. For example, in a case where a composite is used as a case of a predetermined electronic component, a composite having a predetermined shape can be produced using a pressing plate having a suitable dimension and shape for the electronic component to be used.

When the layered first portion 9 and second portion 9A are laminated with each other, the surface in which the first portion and/or the second portion is laminated may be roughened. When the surface is roughened, the adhesiveness of the lamination surface can be improved. As the method of roughening the surface, a method of reducing the blending amount of the resin (B) to be used and exposing the fiber filler (A) to the surface when the first portion 9 and/or the second portion 9A is produced using the paper-making method can be exemplified.

Further, in a case where one of the first portion 9 and the second portion 9A contains a thermoplastic resin and the other contains a thermosetting resin, the adhesiveness of the lamination surface can be improved by blending the thermoplastic resin with the thermosetting resin. This is because the thermoplastic resin is melted in the thermosetting resin and the melted resin functions as a binder when the first portion 9 and the second portion 9A are overlapped with each other and then pressed while being heated.

In the present embodiment, as illustrated in FIG. 10(b), a composite 2A′ may include at least one third portion 9B. The third portion 9B is a portion which is formed of a third fiber filler and a third resin and obtained by subjecting the third fiber filler and the third resin to paper-making. The third portion 9B is formed of a composite material composition containing the fiber filler (A) and the resin (B) which are the same as those used for producing the above-described paper-making sheet and can be produced using a production method which is the same method of producing the above-described paper-making sheet. The fiber filler (A), the resin (B), and other components used for the third portion 9B may be the same as or different from those used for the first portion 9 and the second portion 9A.

In the present embodiment, the composite may further include at least one metal portion made of a metal. The metal portion may be laminated between any of the first portion 9, the second portion 9A, and the third portion 9B or on any surface thereof in a case where the metal portion is layered. By providing the metal portion, the impact resistance of a composite to be obtained can be improved.

According to an example of the present embodiment, by adjusting materials used for respective portions constituting a composite, it is possible to form a composite by combining portions having desired characteristics. For example, a composite can be prepared such that the first portion 9 and the third portion 9B have thermal conductivity and the second portion 9A has electromagnetic wave shielding performance. Such a composite can be used as a case that accommodates an electronic device. Specific examples thereof include a case that accommodates a smartphone, a case that accommodates an inverter, and a case that accommodates a battery. Such cases can be applied to a vehicle.

### Third Embodiment

The outline of a composite according to a third embodiment of the present invention will be described with reference to FIG. 12.

As illustrated in FIG. 12(a), a composite 2B includes a first portion 9 which contains a first fiber filler and a first resin and is obtained by subjecting the first fiber filler and the first resin to paper-making and a second portion 9A which contains a second fiber filler and a second resin and is obtained by subjecting the second fiber filler and the second resin to paper-making.

In the present embodiment, the first portion 9 and the second portion 9A are plate-like, and one sheet of plate-like member is formed by the side surface of the first portion 9 and the side surface of the second portion 9A being bonded to each other and the first portion 9 and the second portion 9A being integrated with each other.

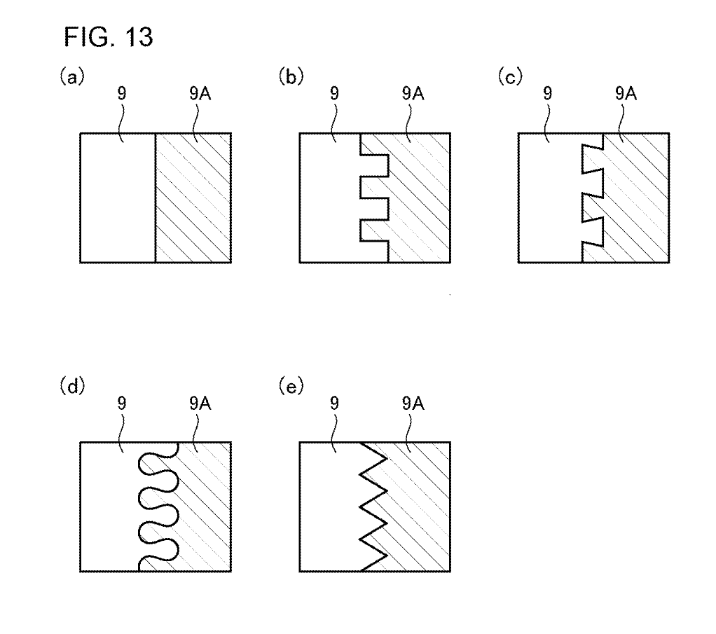

In the example of the present embodiment, the side surface of the first portion 9 and the side surface of the second portion 9A have a flat surface, a curved surface, or an uneven shape, and these side surfaces are engaged with each other. As illustrated in FIGS. 13(a) to 13(e), the side surfaces of the first portion 9 and the second portion 9A may have a shape of a straight line, a rectangle, a trapezoid, a circle, or a waveform, and the side surfaces are engaged with each other such that these shapes are fitted to each other. The shapes of the side surfaces are not limited to the shapes illustrated in FIG. 13.

Such a composite can be prepared by preparing two sheets of paper-making sheets in the same manner as the method of producing the paper-making sheet 8 illustrated in FIG. 5 described above, performing post-processing on the paper-making sheets using a water jet or a punching blade to be processed so as for the sheets have desired shapes, for example, illustrated in FIGS. 13(a) to 13(e), and performing press forming on these two sheets of processed paper-making sheets to be engaged with each other. Alternatively, in a stage of performing press forming on aggregates 8′ illustrated in FIG. 5(f) described above, the aggregates 8′ are prepared to have a desired shape using a pressing plate 71 corresponding to a predetermined shape and then the sheets may be engaged with each other.

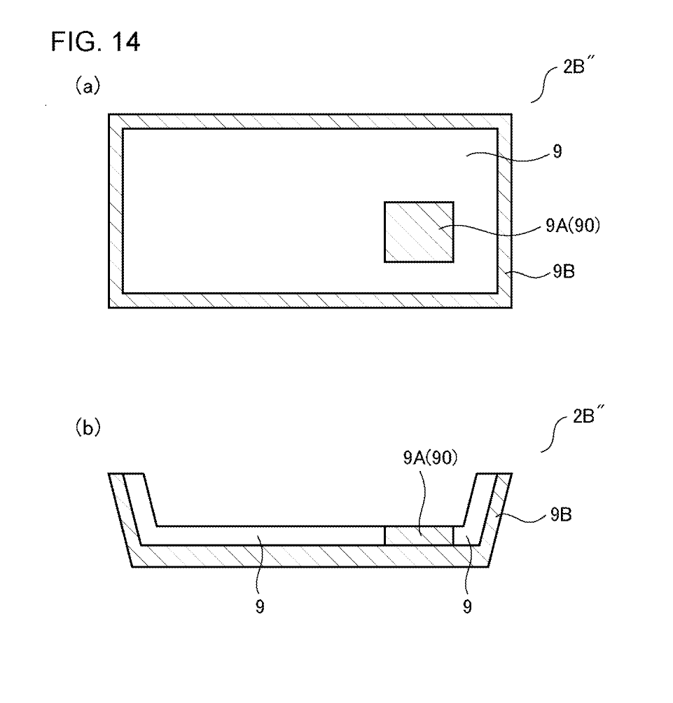

In the example of the present embodiment, the opening portion 90 may be formed in the first portion 9 (FIGS. 14(a) and 14(b)). Further, the second portion 9A may be fitted to the opening portion 90 (FIGS. 14(a) and 14(b)). FIG. 14(a) is a top view of a composite 2B″ and FIG. 14(b) is a cross-sectional view of the composite 2B″. The shape of the opening portion 90 can be changed according to the usage of the composite. The composite having a structure in which the second portion 9A is fitted to a portion of the first portion 9 can be prepared, for example, according to the following method.

The opening portion 90 can be prepared by preparing a paper-making sheet in the same manner as the method of producing the paper-making sheet 8 illustrated in FIG. 5 described above and by performing post-processing on the paper-making sheet using a water jet or a punching blade.

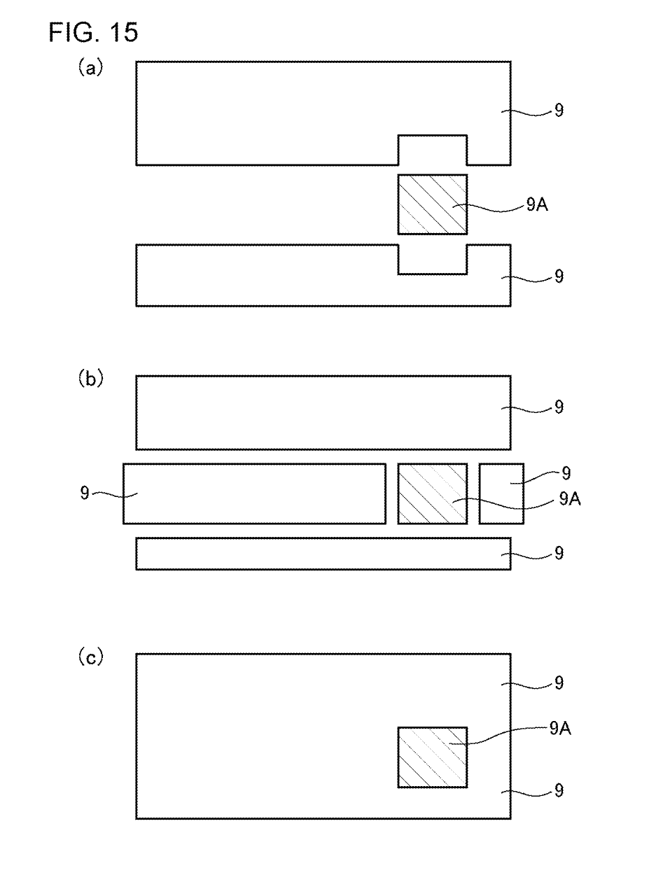

Otherwise, in a stage of performing press forming on aggregates 8′ illustrated in FIG. 5(f) described above, a piece of the first portion with an uneven shape is prepared (FIG. 15(a)) at the stage of performing press forming using the pressing plate 71 having a desired shape. The first portion 9 having the opening portion 90 can be prepared by performing press forming on one of two sheets of the first portion having uneven portions. Next, a composite according to the present embodiment can be prepared by fitting the second portion 9A to the opening portion 90 of the first portion 9 (FIG. 15(c)).

Alternatively, as illustrated in FIG. 15(b), a composite illustrated in FIG. 15(c) may be prepared by preparing each portion which becomes the first portion 9 and each portion which becomes the second portion 9(b) and then combining these.

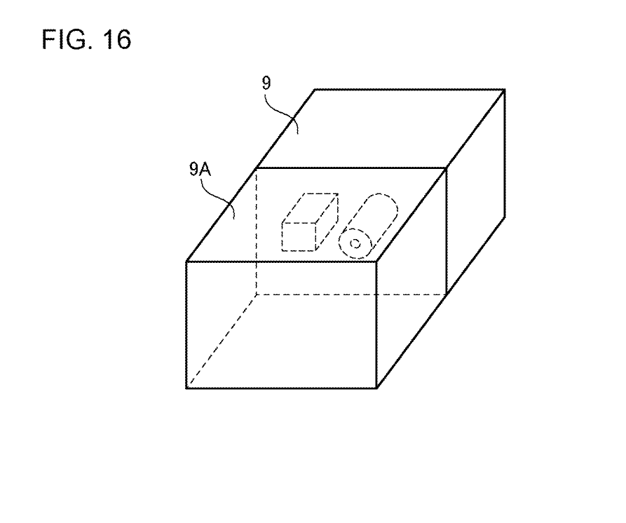

In the example of the present embodiment, the first portion 9 and the second portion 9A can be engaged with each other using the first portion 9 and the second portion 9A having shapes of a boss, a rib, a projection, and the like (FIG. 16). The portion having a projection with a predetermined shape can be prepared according to the following method. FIG. 16 illustrates projections having a circular shape and a rectangular shape, but the projections can have optional shapes.

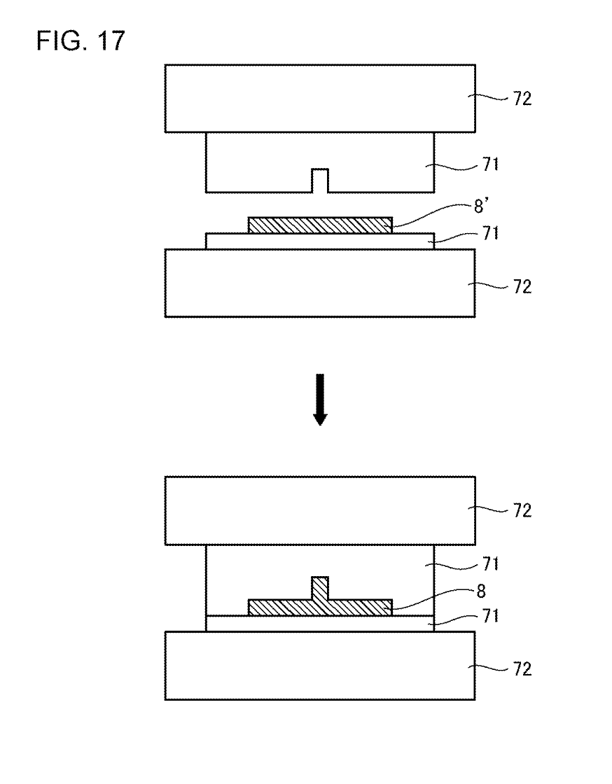

First, sheet-like aggregates 8′ are prepared in the same manner as the method of producing the paper-making sheet 8 illustrated in FIGS. 5(a) to 5(e) described above. Next, illustrated in FIG. 17, the sheet-like aggregates 8′ are subjected to heat pressing with a pressing plate 71 having a concave portion. At this time, the sheet-like aggregates 8′ with fluidity fill the concave portion of the pressing plate 71, thereby forming a projection. A portion having a projection with a desired shape can be prepared using a pressing plate having an optional shape as a pressing plate 71.

In the present embodiment, as illustrated in FIGS. 12(b) and 14, the composites (2B′ and 2B″) may include at least one third portion (9B). The third portion (9B) is a portion that contains the third fiber filler and the third resin and obtained by subjecting the third fiber filler and the third resin to paper-making. The third portion (9B) is formed of the composite material composition containing the fiber filler (A) and the resin (B), similar to those used for producing the above-described paper-making sheet, and can be produced according to the same production method used for producing the above-described paper-making sheet.

Such composites 2B′ and 2B″ can be bent to have a desired form by being heated and pressed using a pressing plate in an uneven shape as illustrated in FIG. 11. The composites which are subjected to bending processing in this manner can be used as a case of an electronic device.

For example, in a case where the electronic device is a smartphone, the composite 2B″ is formed in a shape suitable for accommodating a smartphone as illustrated in FIG. 14. In this case, the first portion 9 prepared from a paper-making sheet with high bending strength is provided in a portion of the composite 2B″ in contact with the smartphone. A region of the first portion 9 in contact with a heating portion of the smartphone is provided with the opening portion 90 and the second portion 9A prepared from the paper-making sheet which has high thermal emissivity is fitted to the opening portion 90. In addition, the third portion 9B covering the first portion 9 and the second portion 9A is prepared from the paper-making sheet having electromagnetic wave shielding performance that protects the smartphone from electromagnetic waves.

Hereinbefore, the embodiments of the present invention have been described with reference to the drawings, but these are merely examples of the present invention and various configurations other than those described above can be employed.

For example, in the first embodiment, the paper-making sheet 8 having a rectangular opening portion is described as an example, but the shape of the opening portion can be optional.

Further, in the second and third embodiments, the composite including the first and the second portions with layered and plate-like shapes has been described as an example respectively, but any one or both of the plate-like first and second portions may have a lamination structure.

### EXAMPLES

Hereinafter, the present invention will be described in detail with reference to Examples, but the present invention is not limited thereto. Further, “parts” and “%” described in Examples respectively indicate “parts by mass” and “% by mass.”

The raw materials described in Production Examples are expressed by parts by mass from which the moisture content contained in advance is removed.

### Examples

### Paper-Making Sheet for Shielding Electromagnetic Waves

1. Preparation of Composite Resin Composition

### (1) Production Example 1

45 parts of a solid resol resin (PR-51723, manufactured by Sumitomo Bakelite Co., Ltd.) which was crushed using an atomizer crusher to have an average particle diameter of 100 μm, 2 parts of Bentonite (Kunipia (trade name) manufactured by KUNIMINE INDUSTRIES CO., LTD.), 1 part of stainless fiber having a fiber length of 5 mm and a fiber diameter of 6 μm (NASLON (trade name) manufactured by Nippon Seisen Co., Ltd.), 12 parts of Kevlar (registered trademark) pulp 1F303 (manufactured by DU PONT-TORAY CO., LTD.), and 40 parts of Technora (registered trademark) fiber T32PNW (manufactured by TEIJIN TECHNO PRODUCTS LIMITED) were added to 10000 parts of water, the mixture was stirred using a disperser for 30 minutes, 900 ppm of polyethylene oxide having a molecular weight of 1000000 (manufactured by Wako Pure Chemical Industries, Ltd.) which was solved in water in advance was added thereto based on the total mass of the above-described all constituent materials, and then the constituent materials were aggregated in flocks. The aggregates were separated from water using a metal mesh having 80 meshes, dehydrated and pressed, and put into a drier at a temperature of 70° C. for 6 hours to be dried, thereby obtaining a composite resin composition with a yield of 99%. Further, a method of measuring the yield will be described below in detail.

### (2) Production Example 2

45 parts of a solid resol resin (PR-51723, manufactured by Sumitomo Bakelite Co., Ltd.) which was crushed using an atomizer crusher to have an average particle diameter of 100 μm, 5 parts of Bentonite (Kunipia (trade name) manufactured by KUNIMINE INDUSTRIES CO., LTD.), 4 parts of stainless fiber having a fiber length of 5 mm and a fiber diameter of 6 μm (NASLON (trade name) manufactured by Nippon Seisen Co., Ltd.), 6 parts of Kevlar (registered trademark) pulp 1F303 (manufactured by DU PONT-TORAY CO., LTD.), and 40 parts of Technora (registered trademark) fiber T32PNW (manufactured by TEIJIN TECHNO PRODUCTS LIMITED) were added to 10000 parts of water, the mixture was stirred using a disperser for 30 minutes, 0.3% of polyethylene oxide having a molecular weight of 1000000 (manufactured by Wako Pure Chemical Industries, Ltd.) which was solved in water in advance was added thereto based on the total mass of the above-described all constituent materials, and then the constituent materials were aggregated in flocks. The aggregates were separated from water using a metal mesh having 80 meshes, dehydrated and pressed, and put into a drier at a temperature of 70° C. for 6 hours to be dried, thereby obtaining a composite resin composition with a yield of 99%.

### (3) Production Example 3

30 parts of a solid resol resin (PR-51723, manufactured by Sumitomo Bakelite Co., Ltd.) which was crushed using an atomizer crusher to have an average particle diameter of 100 μm, 3 parts of Bentonite (Kunipia (trade name) manufactured by KUNIMINE INDUSTRIES CO., LTD.), 32 parts of stainless fiber having a fiber length of 5 mm and a fiber diameter of 6 μm (NASLON (trade name) manufactured by Nippon Seisen Co., Ltd.), 10 parts of Kevlar (registered trademark) pulp 1F303 (manufactured by DU PONT-TORAY CO., LTD.), and 25 parts of Technora (registered trademark) fiber T32PNW (manufactured by TEIJIN TECHNO PRODUCTS LIMITED) were added to 10000 parts of water, the mixture was stirred using a disperser for 30 minutes, 0.5% of polyethylene oxide having a molecular weight of 1000000 (manufactured by Wako Pure Chemical Industries, Ltd.) which was solved in water in advance was added thereto based on the total mass of the above-described all constituent materials, and then the constituent materials were aggregated in flocks. The aggregates were separated from water using a metal mesh having 80 meshes, dehydrated and pressed, and put into a drier at a temperature of 70° C. for 6 hours to be dried, thereby obtaining a composite resin composition with a yield of 96%.

### (4) Production Example 4

45 parts of an acrylonitrile-styrene copolymer (AS) resin (CEVIAN N (trade name) manufactured by Daicel Industry Co., Ltd.) which was crushed using a freeze crusher to have an average particle diameter of 300 μm, 5 parts of scaly silica microparticles (SUNLOVELY (trade name) manufactured by AGC Si-Tech Co., Ltd.), 5 parts of stainless fiber having a fiber length of 5 mm and a fiber diameter of 6 μm (NASLON (trade name) manufactured by Nippon Seisen Co., Ltd.), and 45 parts of polyvinyl alcohol fibers (Vinylon (trade name) manufactured by KURARAY CO., LTD.) having a fiber diameter of 22 μm and a fiber length of 5 mm were added to 10000 parts of water, the mixture was stirred using a disperser for 30 minutes, 0.4% of cationic polyacrylamide (manufactured by Harima Chemicals, Inc.) which was solved in water in advance was added thereto based on the total mass of the above-described all constituent materials, and then the constituent materials were aggregated in flocks. The aggregates were separated from water using a metal mesh having 40 meshes, dehydrated and pressed, and put into a drier at a temperature of 130° C. for 6 hours to be dried, thereby obtaining a composite resin composition with a yield of 92%.

### (5) Production Example 5

10 parts of epoxy resin 1002 (manufactured by Mitsubishi Chemical Corporation) which was crushed using a high-pressure homogenizer to have an average particle diameter of 30 μm, 1 part of imidazole-based epoxy resin curing agent 2PZ-PW (manufactured by SHIKOKU CHEMICALS CORPORATION), 3 parts of synthetic saponite (Sumecton SA (trade name) manufactured by KUNIMINE INDUSTRIES CO., LTD.), 77 parts of copper fibers having a fiber length of 3 mm and a fiber diameter of 60 μm (manufactured by Kogi Corporation Co., Ltd.), 5 parts of stainless fiber having a fiber length of 5 mm and a fiber diameter of 6 μm (NASLON (trade name) manufactured by Nippon Seisen Co., Ltd.), and 4 parts of cellulose pulp (NDPT (trade name) Nippon Paper Chemicals Co., Ltd.) were added to 10000 parts of water, the mixture was stirred using a disperser for 30 minutes, 0.3% of cationic starch SC-5 (manufactured by Sanwa Starch Co., Ltd.) which was solved in water in advance was added thereto based on the total mass of the above-described all constituent materials, and then the constituent materials were aggregated in flocks. The aggregates were separated from water using a metal mesh having 40 meshes, dehydrated and pressed, and put into a drier at a temperature of 100° C. for 4 hours to be dried, thereby obtaining a composite resin composition with a yield of 95%.

2. Preparation of Paper-Making Sheet

### (1) Production Example 6

The composite resin composition obtained in Production Example 1 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (2) Production Example 7

The composite resin composition obtained in Production Example 2 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (3) Production Example 8

The composite resin composition obtained in Production Example 3 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (4) Production Example 9

The composite resin composition obtained in Production Example 4 was set in a mold coated with a release agent, compression forming was performed on the composite resin composition at a temperature of 200° C. under the surface pressure of 15 MPa for 10 minutes, and the mold was cooled to a temperature of 50° C., thereby obtaining a paper-making sheet having a dimension of a height of 10 cm, a width of 10 cm, and a thickness of 2 mm.

### (5) Production Example 10

The composite resin composition obtained in Production Example 5 was set in a mold coated with a release agent and compression forming was performed on the composite resin composition at a temperature of 160° C. under the surface pressure of 10 MPa for 60 minutes, thereby obtaining a paper-making sheet having a dimension of a height of 10 cm, a width of 10 cm, and a thickness of 2 mm.

Evaluation of characteristics described below was performed using paper-making sheets obtained in Production Examples 6 to 10. The results thereof are listed in Table 1.

TABLE 1

| | Specific | Electric field | Electric field | Electric field | Magnetic field | | Bending | Linear |
|---|---|---|---|---|---|---|---|---|
| | gravity of | wave shielding | wave shielding | wave shielding | wave shielding | Bending | elastic | expansion |
| | paper-making | properties at | properties at | properties at | properties at | strength | modulus | coefficient |
| | sheet | 100 MHz (dB) | 500 MHz (dB) | 800 MHz (dB) | 800 MHz (dB) | (MPa) | (GPa) | (ppm/° C.) |
| Production | 1.30 | 28 | 21 | 20 | 5 | 330 | 12 | 5 |
| Example 6 | | | | | | | | |
| Production | 1.35 | 48 | 42 | 40 | 30 | 330 | 13 | 6 |
| Example 7 | | | | | | | | |
| Production | 1.81 | 70 | 55 | 48 | 55 | 380 | 16 | 5 |
| Example 8 | | | | | | | | |
| Production | 1.27 | 50 | 44 | 42 | 42 | 90 | 8 | 46 |
| Example 9 | | | | | | | | |
| Production | 4.48 | 65 | 50 | 44 | 50 | 80 | 17 | 37 |
| Example 10 | | | | | | | | |

3. Evaluation Method of Characteristics

3.1 Composite Resin Composition

(1) Yield

The yield was calculated according to the following formula.

Yield(%)=(weight of obtained composite resin composition/total weight of prepared raw materials of composite resin composition)×100

The weight of the composite resin composition after drying was used for the obtained composite resin composition and the weight from which the moisture content was removed was used for the total weight of the prepared raw materials of the composite resin composition.

3.2 Paper-Making Sheet

(1) Measurement of Specific Gravity

The specific gravity thereof was measured in conformity with JIS K 6911 (thermosetting plastic general test method). A test piece which was cut out from the paper-making sheet so as to have a dimension of a height of 2 cm, a width of 2 cm, and a thickness of 2 mm was used.

(2) Measurement of Electromagnetic Wave Shielding Rate

A paper-making sheet with a dimension of a height of 12 cm, a width of 12 cm, and a thickness of 1 mm was prepared under the forming conditions which were the same as those of the obtained paper-making sheet with a dimension of a height of 10 cm, a width of 10 cm, and a thickness of 2 mm and the prepared paper-making sheet was used as a test piece. Next, the evaluation was performed according to a KEC method. The KEC method, which was proposed by KEC Electronic Industry Development Center, is a method of measuring the attenuance of the electromagnetic wave through a test piece using a spectrum analyzer after the test piece is interposed in a symmetrically divided shield box.

An example of the relationship between the electromagnetic wave shielding properties and the electromagnetic wave shielding rate is as follows.

The electromagnetic wave shielding properties 60 dB indicates an electromagnetic wave shielding rate of 99.9%.

The electromagnetic wave shielding properties 40 dB indicates an electromagnetic wave shielding rate of 99.0%.

The electromagnetic wave shielding properties 20 dB indicates an electromagnetic wave shielding rate of 90.0%.

(3) Bending Test

The bending test was performed in conformity with JIS K 6911 (thermosetting plastic general test method). A test piece which was cut out from the paper-making sheet so as to have a dimension of a height of 50 cm, a width of 25 cm, and a thickness of 2 mm was used. The distance between fulcrums of the bending test was 32 mm.

(4) Measurement of Linear Expansion Coefficient in Planar Direction

A paper-making sheet with a dimension of a height of 5 mm, a width of 30 mm, and a length of 10 mm was prepared under the condition of the forming time being three times that in which a paper-making sheet with a dimension of a height of 10 cm, a width of 10 cm, and a thickness of 2 mm was obtained and then cut into test pieces with a dimension of a height of 5 mm, a width of 5 mm, and a length of 10 mm, and then the linear expansion coefficient in the length direction was measured using a thermo-mechanical analyzer (TMA-6000, manufactured by Seiko Instruments, Inc.). The temperature increasing rate was set to 5° C./min and the linear expansion coefficient (al) was acquired in a temperature range of 80° C. to 120° C.

In all Production Examples 1 to 5, composite resin compositions were obtained with high yields. Further, in all Production Examples 6 to 10, the electric field wave shielding properties at 800 MHz were equal to or higher than 20 dB, the bending strength was equal to or more than 80 MPa, and the bending elastic modulus was equal to or more than 8 GPa. In addition, the specific gravity was equal to or more than 1 and equal to or less than 5 and the linear thermal coefficient in the planar direction was equal to or more than 0.1 ppm/° C. and equal to or less than 50 ppm/° C. Thus, it was understood that a paper-making sheet with excellent balance among characteristics was obtained.

In addition, when the paper-making sheet obtained in Production Example 6 was laminated with a build-up substrate and thermally cured so that the paper-making sheet was attached to the build-up substrate, it was possible to shield the electromagnetic waves and reinforce the substrate. Similarly, when each of the paper-making sheets obtained in Production Examples 7 to 10 was laminated with a build-up substrate and thermally cured so that the paper-making sheet was attached to the build-up substrate, it was possible to shield the electromagnetic waves and reinforce the substrate.

(Paper-Making Sheet for Heat Radiation)

1. Preparation of Composite Resin Composition

### (1) Production Example 11

24 parts of epoxy resin 1002 (manufactured by Mitsubishi Chemical Corporation) which was crushed using a high-pressure homogenizer to have an average particle diameter of 30 μm, 1 part of imidazole-based epoxy resin curing agent 2PZ-PW (manufactured by SHIKOKU CHEMICALS CORPORATION), 5 parts of synthetic saponite (Sumecton SA (trade name) manufactured by KUNIMINE INDUSTRIES CO., LTD.), 60 parts of aluminum fibers having a fiber length of 3 mm and a fiber diameter of 60 μm (material: A1070, manufactured by Kogi Corporation Co., Ltd.), and 10 parts of cellulose pulp (NDPT (trade name) Nippon Paper Chemicals Co., Ltd.) were added to 10000 parts of water, the mixture was stirred using a disperser for 30 minutes, 0.4% of cationic starch SC-5 (manufactured by Sanwa Starch Co., Ltd.) which was solved in water in advance was added thereto based on the mass of the constituent materials, and then the constituent materials were aggregated in flocks. The aggregates were separated from water using a metal mesh having 40 meshes, dehydrated and pressed, and put into a drier at a temperature of 100° C. for 4 hours to be dried, thereby obtaining a composite resin composition with a yield of 94%. The method of measuring the yield is described below.

### (2) Production Example 12

10 parts of epoxy resin 1002 (manufactured by Mitsubishi Chemical Corporation) which was crushed using a high-pressure homogenizer to have an average particle diameter of 30 μm, 1 part of imidazole-based epoxy resin curing agent 2PZ-PW (manufactured by SHIKOKU CHEMICALS CORPORATION), 3 parts of synthetic saponite (Sumecton SA (trade name) manufactured by KUNIMINE INDUSTRIES CO., LTD.), 82 parts of copper fibers having a fiber length of 3 mm and a fiber diameter of 60 μm (manufactured by Kogi Corporation Co., Ltd.), and 4 parts of cellulose pulp (NDPT (trade name) Nippon Paper Chemicals Co., Ltd.) were added to 10000 parts of water, the mixture was stirred using a disperser for 30 minutes, 0.3% of cationic starch SC-5 (manufactured by Sanwa Starch Co., Ltd.) which was solved in water in advance was added thereto based on the mass of the constituent materials, and then the constituent materials were aggregated in flocks. The aggregates were separated from water using a metal mesh having 40 meshes, dehydrated and pressed, and put into a drier at a temperature of 100° C. for 4 hours to be dried, thereby obtaining a composite resin composition with a yield of 95%.

### (3) Production Example 13

40 parts of a solid resol resin (PR-51723, manufactured by Sumitomo Bakelite Co., Ltd.) which was crushed using an atomizer crusher to have an average particle diameter of 100 μm, 5 parts of Bentonite (Kunipia (trade name) manufactured by KUNIMINE INDUSTRIES CO., LTD.), 25 parts of aluminum fibers having a fiber length of 3 mm and a fiber diameter of 90 μm (material: A1070, manufactured by Kogi Corporation Co., Ltd.), 5 parts of Kevlar (registered trademark) pulp 1F303 (manufactured by DU PONT-TORAY CO., LTD.), and 25 parts of Technora (registered trademark) fiber T32PNW (manufactured by TEIJIN TECHNO PRODUCTS LIMITED) were added to 10000 parts of water, the mixture was stirred using a disperser for 30 minutes, 0.2% of polyethylene oxide having a molecular weight of 1000000 (manufactured by Wako Pure Chemical Industries, Ltd.) which was solved in water in advance was added thereto based on the mass of the constituent materials, and then the constituent materials were aggregated in flocks. The aggregates were separated from water using a metal mesh having 40 meshes, dehydrated and pressed, and put into a drier at a temperature of 70° C. for 6 hours to be dried, thereby obtaining a composite resin composition with a yield of 97%.

### (4) Production Example 14

35 parts of a solid resol resin (PR-51723, manufactured by Sumitomo Bakelite Co., Ltd.) which was crushed using an atomizer crusher to have an average particle diameter of 100 μm, 5 parts of Bentonite (Kunipia (trade name) manufactured by KUNIMINE INDUSTRIES CO., LTD.), 40 parts of aluminum fibers having a fiber length of 3 mm and a fiber diameter of 90 μm (material: A1070, manufactured by Kogi Corporation Co., Ltd.), 5 parts of Kevlar (registered trademark) pulp 1F303 (manufactured by DU PONT-TORAY CO., LTD.), and 15 parts of Technora (registered trademark) fiber T32PNW (manufactured by TEIJIN TECHNO PRODUCTS LIMITED) were added to 10000 parts of water, the mixture was stirred using a disperser for 30 minutes, 0.5% of polyethylene oxide having a molecular weight of 1000000 (manufactured by Wako Pure Chemical Industries, Ltd.) which was solved in water in advance was added thereto based on the mass of the constituent materials, and then the constituent materials were aggregated in flocks. The aggregates were separated from water using a metal mesh having 40 meshes, dehydrated and pressed, and put into a drier at a temperature of 70° C. for 6 hours to be dried, thereby obtaining a composite resin composition with a yield of 94%.

### (5) Production Example 15

35 parts of a solid resol resin (PR-51723, manufactured by Sumitomo Bakelite Co., Ltd.) which was crushed using an atomizer crusher to have an average particle diameter of 100 μm, 5 parts of Bentonite (Kunipia (trade name) manufactured by KUNIMINE INDUSTRIES CO., LTD.), 40 parts of aluminum fibers having a fiber length of 3 mm and a fiber diameter of 90 μm (material: A5052, manufactured by Kogi Corporation Co., Ltd.), 5 parts of Kevlar (registered trademark) pulp 1F303 (manufactured by DU PONT-TORAY CO., LTD.), and 15 parts of Technora (registered trademark) fiber T32PNW (manufactured by TEIJIN TECHNO PRODUCTS LIMITED) were added to 10000 parts of water, the mixture was stirred using a disperser for 30 minutes, 0.5% of polyethylene oxide having a molecular weight of 1000000 (manufactured by Wako Pure Chemical Industries, Ltd.) which was solved in water in advance was added thereto based on the mass of the constituent materials, and then the constituent materials were aggregated in flocks. The aggregates were separated from water using a metal mesh having 40 meshes, dehydrated and pressed, and put into a drier at a temperature of 70° C. for 6 hours to be dried, thereby obtaining a composite resin composition with a yield of 94%.

### (6) Production Example 16

30 parts of an acrylonitrile-styrene copolymer (AS) resin (CEVIAN N (trade name) manufactured by Daicel Industry Co., Ltd.) which was crushed using a freeze crusher to have an average particle diameter of 200 μm, 5 parts of scaly silica microparticles (SUNLOVELY (trade name) manufactured by AGC Si-Tech Co., Ltd.), 10 parts of copper fibers having a fiber length of 3 mm and a fiber diameter of 90 μm (manufactured by Kogi Corporation Co., Ltd.), 40 parts of copper powder having an average particle diameter of 20 μm (CUE13PB (trade name), manufactured by KOJUNDO CHEMICAL LABORATORY CO., LTD.), and 15 parts of polyvinyl alcohol fibers (Vinylon (trade name) manufactured by KURARAY CO., LTD.) having a fiber diameter of 22 μm and a fiber length of 5 mm were added to 10000 parts of water, the mixture was stirred using a disperser for 30 minutes, 0.5% of cationic polyacrylamide (manufactured by Harima Chemicals, Inc.) which was solved in water in advance was added thereto based on the mass of the constituent materials, and then the constituent materials were aggregated in flocks. The aggregates were separated from water using a metal mesh having 80 meshes, dehydrated and pressed, and put into a drier at a temperature of 130° C. for 6 hours to be dried, thereby obtaining a composite resin composition with a yield of 90%.

2. Preparation of Paper-Making Sheet

### (1) Production Example 17

The composite resin composition obtained in Production Example 11 was set in a mold coated with a release agent and compression forming was performed on the composite resin composition at a temperature of 160° C. under the surface pressure of 10 MPa for 60 minutes, thereby obtaining a paper-making sheet having a dimension of a height of 10 cm, a width of 10 cm, and a thickness of 2 mm.

### (2) Production Example 18

The composite resin composition obtained in Production Example 12 was set in a mold coated with a release agent and compression forming was performed on the composite resin composition at a temperature of 160° C. under the surface pressure of 10 MPa for 60 minutes, thereby obtaining a paper-making sheet having a dimension of a height of 10 cm, a width of 10 cm, and a thickness of 2 mm.

### (3) Production Example 19

The composite resin composition obtained in Production Example 13 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (4) Production Example 20

The composite resin composition obtained in Production Example 14 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (5) Production Example 21

The composite resin composition obtained in Production Example 15 was set in a mold coated with a release agent and compression forming was performed on the composite resin composition at a temperature of 180° C. under the surface pressure of 30 MPa for 10 minutes, thereby obtaining a paper-making sheet having a dimension of a height of 10 cm, a width of 10 cm, and a thickness of 2 mm.

### (6) Production Example 22

The composite resin composition obtained in Production Example 16 was set in a mold coated with a release agent, compression forming was performed on the composite resin composition at a temperature of 200° C. under the surface pressure of 10 MPa for 10 minutes, and the temperature of the mold was cooled to 50° C., thereby obtaining a paper-making sheet having a dimension of a height of 10 cm, a width of 10 cm, and a thickness of 2 mm.

Evaluation of characteristics described below was performed using paper-making sheets obtained in Production Examples 17 to 22. The results thereof are listed in Table 2.

TABLE 2

| | | Thermal | Thermal | | | |
|---|---|---|---|---|---|---|
| | Specific gravity | conductivity | conductivity | Bending | | Linear expansion |
| | of paper-making | in planar | in thickness | strength | Bending elastic | coefficient |
| | sheet | direction (W/mK) | direction (W/mK) | (MPa) | modulus (GPa) | (ppm/° C.) |
| Production | 1.92 | 38.2 | 3.0 | 90 | 17 | 35 |
| Example 17 | | | | | | |
| Production | 4.48 | 50.5 | 3.4 | 80 | 17 | 40 |
| Example 18 | | | | | | |
| Production | 1.56 | 5.2 | 0.6 | 270 | 12 | 10 |
| Example 19 | | | | | | |
| Production | 1.73 | 18.2 | 1.3 | 210 | 15 | 20 |
| Example 20 | | | | | | |
| Production | 1.72 | 8.0 | 1.1 | 220 | 16 | 22 |
| Example 21 | | | | | | |
| Production | 2.29 | 5.1 | 2.5 | 80 | 9 | 47 |
| Example 22 | | | | | | |

3. Evaluation Method of Characteristics (First Method)

3.1 Composite Resin Composition

(1) Yield

The yield was calculated according to the following formula.

Yield(%)=(weight of obtained composite resin composition/total weight of prepared raw materials of composite resin composition)×100

The weight of the composite resin composition after drying was used for the obtained composite resin composition and the weight from which the moisture content was removed was used for the total weight of the prepared raw materials of the composite resin composition.

3.2 Paper-Making Sheet

(1) Measurement of Specific Gravity

The specific gravity thereof was measured in conformity with JIS K 6911 (thermosetting plastic general test method). A test piece which was cut out from the paper-making sheet so as to have a dimension of a height of 2 cm, a width of 2 cm, and a thickness of 2 mm was used.

(2) Measurement of Thermal Conductivity

A paper-making sheet with a dimension of a height of 10 mm, a width of 10 mm, and a length of 3 mm was prepared under the condition of the forming time being three times that in which a paper-making sheet with a dimension of a height of 10 cm, a width of 10 cm, and a thickness of 2 mm was obtained, for measurement in the planar direction. Here, the planar direction is a direction along the surface of the fiber fillers in the extension direction. Further, a paper-making sheet with a dimension of a height of 10 cm, a width of 10 cm, and a length of 1.5 mm was prepared under the same conditions as the forming conditions in which a paper-making sheet with a dimension of a height of 10 cm, a width of 10 cm, and a thickness of 2 mm was obtained, for measurement in the thickness direction. Obtained respective paper-making sheets were cut so as to have a dimension of a height of 10 mm, a width of 10 mm, and a length of 1.5 mm and then these cut paper-making sheets were set as test pieces. Next, the thermal conductivity of plate-like test pieces in the length direction was measured according to a laser flash method using Xe flash analyzer LFA447 (manufactured by NETZSCH, Inc.). The measurement was performed at a temperature of 25° C. under an air atmosphere.

(3) Bending Test

The bending test was performed in conformity with JIS K 6911 (thermosetting plastic general test method). A test piece which was cut out from the paper-making sheet so as to have a dimension of a height of 50 mm, a width of 25 mm, and a thickness of 2 mm was used. The distance between fulcrums of the bending test was 32 mm.

(4) Measurement of Linear Expansion Coefficient

A paper-making sheet with a dimension of a height of 5 mm, a width of 30 mm, and a length of 10 mm was prepared under the condition of the forming time being three times that in which a paper-making sheet of a height of 10 cm, a width of 10 cm, and a thickness of 2 mm was obtained and then cut into test pieces with a dimension of a height of 5 mm, a width of 5 mm, and a length of 10 mm, and then the linear expansion coefficient in the length direction was measured using a thermo-mechanical analyzer (TMA-6000, manufactured by Seiko Instruments, Inc.). The temperature increasing rate was set to 5° C./min and the linear expansion coefficient (α1) was acquired in a temperature range of 80° C. to 120° C.

Evaluation of characteristics described below was performed using paper-making sheets obtained in Production Examples 19 and 20. The results thereof are listed in Table 3.

TABLE 3

| | Infrared emissivity |
|---|---|
| | (%) |
| Production | 0.91 |
| Example 19 | |
| Production | 0.89 |
| Example 20 | |

4. Evaluation Method of Characteristics (Second Method)

4.1 Paper-Making Sheet

(1) Measurement of Infrared Emissivity

After test pieces were heated and the temperature thereof reached the equilibrium temperature, infrared spectral radiation spectra were measured under the conditions of a measurement temperature of 80° C. and a measurement wavelength of 4.4 μm to 15.4 μm, and the integral emissivity (%) was acquired using FT-IR (Fourier transform infrared spectrophotometer). In addition, test pieces cut out from the paper-making sheets so as to have a dimension of a height of 4 cm, a width of 4 cm, and a thickness of 1 mm were used.

In all Production Examples 11 to 16, composite resin compositions with high yields were obtained. Further, in all Production Examples 17 to 22, the thermal conductivity in the planar direction was equal to or more than 5 W/mK, the thermal conductivity in the thickness direction was less than or equal to a half of the thermal conductivity in the planar direction, the bending strength was equal to or more than 80 MPa, and the bending elastic modulus was equal to or more than 8 GPa. In addition, the specific gravity was equal to or more than 1 and equal to or less than 5 and the linear thermal coefficient in the planar direction was equal to or more than 0.1 ppm/° C. and equal to or less than 50 ppm/° C. Thus, it was understood that a paper-making sheet with excellent balance among characteristics was obtained.

Further, in Production Examples 19 to 21, the thermal conductivity in the planar direction was equal to or more than 5 W/mK even in a case where organic fibers were used in combination and thus paper-making sheets which showed excellent thermal conductivity while not being damaged even when organic fibers were used in combination and excellent mechanical characteristics, for example, a bending strength of equal to or more than 200 MPa, were obtained.

Further, when the paper-making sheet obtained in Production Example 19 was laminated on the build-up substrate and thermally cured so that the paper-making sheet was attached to the build-up substrate, it was possible for the substrate to radiate heat.

This application claims priority based on Japanese Patent Application No. 2012-220289 filed on Oct. 2, 2012 and the entire disclosure of which is incorporated herein.

1. A laminate comprising:
a substrate; and
a layer which is provided on the substrate, contains a fiber filler and a resin, and is obtained by subjecting the fiber filler and the resin to paper-making.

2. The laminate according to claim 1, wherein the substrate contains a fiber filler and a resin and is obtained by subjecting the fiber filler and the resin to paper-making.

3. The laminate according to claim 1, wherein the fiber filler has a fiber length of equal to or more than 500 μm.

4. The laminate according to claim 1, wherein the content of the fiber filler in the layer is equal to or more than 20% by mass and equal to or less than 80% by mass based on the layer.

5. The laminate according to claim 1,
wherein a fiber layer formed of the fiber filler is formed in the layer,
the fiber layer is covered with a resin layer formed of the resin, and
a dimension from a center position in a thickness of the fiber layer to one surface of the resin layer is different from a dimension from the center position thereof to another surface of the resin layer.

6. The laminate according to claim 1,
wherein a first layer which is the layer and a second layer are laminated on the substrate, and
the second layer contains a fiber filler and a resin, is obtained by subjecting the fiber filler and the resin to paper-making, and has a different composition from that of the first layer.

7. The laminate according to claim 1, wherein an opening portion is formed on the layer.

8. The laminate according to claim 7, further comprising:
the second layer which is fitted to the opening portion,
wherein the second layer contains a fiber filler and a resin, is obtained by subjecting the fiber filler and the resin to paper-making, and has a different composition from that of the first layer.

9. The laminate according to claim 1, further comprising any one substrate of a circuit substrate and an optical circuit substrate.

10. A composite comprising:
a first portion which contains a first fiber filler and a first resin and is obtained by subjecting the first fiber filler and the first resin to paper-making; and
a second portion which contains a second fiber filler and a second resin and is obtained by subjecting the second fiber filler and the second resin to paper-making.

11. The composite according to claim 10,
wherein the first portion and the second portion are layered, and
the first portion and the second portion are laminated with each other.

12. The composite according to claim 10,
wherein the first portion and the second portion are plate-like,
a side surface of the first portion and a side surface of the second portion are bonded to each other, and
the first portion and the second portion are integrated with each other to form one sheet of a plate-like member.

13. The composite according to claim 12,
wherein the side surface of the first portion and the side surface of the second portion have curved surfaces or uneven shapes, and
the side surface of the first portion is engaged with the side surface of the second portion.

14. The composite according to claim 12,
wherein the first portion has an opening portion, and
the second portion is fitted to the opening portion.

15. The composite according to claim 10, wherein the composition of the first portion is different from the composition of the second portion.

16. The composite according to claim 10, further comprising at least a third portion which contains a third fiber filler and a third resin and is obtained by subjecting the third fiber filler and the third resin to paper-making.

17. The composite according to claim 10, further comprising a metal portion made of a metal.

18. The composite according to claim 10, wherein the fiber filler has a fiber length of equal to or more than 500 μm.

19. The composite according to claim 16, wherein the contents of the first, second, and third fiber fillers in the first, second, and third portions are respectively equal to or more than 20% by mass and equal to or less than 80% by mass based on the total content of the first, second, and third portions.

20. The composite according to claim 16,
wherein a fiber layer formed of the fiber filler is formed in the first, second, and third portions,
the fiber layer is covered with a resin layer formed of the resin, and
a dimension from a center position in the thickness of the fiber layer to one surface of the resin layer is different from a dimension from the center position thereof to another surface of the resin layer.

21. The composite according to claim 10, wherein the composite is subjected to bending processing.

22. The composite according to claim 10, wherein the composite has electromagnetic wave shielding performance.

23. The composite according to claim 10, wherein the composite is a case accommodating an electronic device.
